(19) United States
(12) Patent Application Publication
(10) Pub. No.: US 2022/0343797 A1
(43) Pub. Date: Oct. 27, 2022

(54) SYSTEM, METHOD, AND PROGRAM PRODUCT FOR SIMULATING SPATIAL AND TEMPORAL MAGNETIC PROPERTIES OF CONFIGURABLE MOLECULAR SPINTRONICS DEVICES

(71) Applicants: Pawan Tyagi, Derwood, MD (US); Christopher D'Angelo, Washington, DC (US)

(72) Inventors: Pawan Tyagi, Derwood, MD (US); Christopher D'Angelo, Washington, DC (US)

(21) Appl. No.: 17/722,145

(22) Filed: Apr. 15, 2022

Related U.S. Application Data
(60) Provisional application No. 63/175,613, filed on Apr. 16, 2021.

(51) Int. Cl. G09B 23/26; G01R 33/30; G01R 33/24

(52) U.S. Cl. CPC G09B 23/26; G01R 33/307; G01R 33/243; B82Y 25/00

(57) ABSTRACT

A system and method for simulating the spatial and temporal magnetic properties of configurable nanoscale magnetic molecules is provided comprising steps for simulating molecular spintronics devices (MSD) of different shapes involving thousands of magnetic atoms and molecules, representing complex magnetic molecules as a device element in MSD to use MCSMSD, defining a wide range of magnetic molecule-magnetic electrode interactions in MSD, studying the magnetic anisotropy effect in MSD simulation, studying the effect of electrons in the magnetic electrodes and fluctuations controlling the active molecule population in MSD simulation, studying the effect of defects within insulator competing with magnetic molecules, and harnessing parallel processing capabilities in desktop computers.

### CROSS-REFERENCE TO RELATED APPLICATIONS

The present Utility patent application claims priority benefit of the U.S. provisional application for patent Ser. No. 63/175,613 entitled “Design of Very Complex Molecule Based Spintronics Devices and Materials”, filed on 16 Apr. 2021, under 35 U.S.C. 119(e). The contents of this related provisional application are incorporated herein by reference for all purposes to the extent that such subject matter is not inconsistent herewith or limiting hereof.

### INCORPORATION BY REFERENCE OF SEQUENCE LISTING PROVIDED AS ATEXT FILE

Not applicable.

### FEDERALLY SPONSORED RESEARCH OR DEVELOPMENT

Not applicable.

### REFERENCE TO SEQUENCE LISTING, A TABLE, OR A COMPUTER LISTING APPENDIX

Not applicable.

### COPYRIGHT NOTICE

A portion of the disclosure of this patent document contains material that is subject to copyright protection by the author thereof. The copyright owner has no objection to the facsimile reproduction by anyone of the patent document or patent disclosure for the purposes of referencing as patent prior art, as it appears in the Patent and Trademark Office, patent file or records, but otherwise reserves all copyright rights whatsoever.

### BACKGROUND OF THE RELEVANT PRIOR ART

One or more embodiments of the invention generally relate to simulation systems and methods. More particularly, certain embodiments of the invention relate to systems and methods for simulating the spatial and temporal magnetic properties of configurable nanoscale magnetic molecules connected to two configurable ferromagnetic electrodes at configurable thermal energies and magnetic fields.

The following background information may present examples of specific aspects of the prior art (e.g., without limitation, approaches, facts, or common wisdom) that, while expected to be helpful to further educate the reader as to additional aspects of the prior art, is not to be construed as limiting the present invention, or any embodiments thereof, to anything stated or implied therein or inferred thereupon.

The following is an example of a specific aspect in the prior art that, while expected to be helpful to further educate the reader as to additional aspects of the prior art, is not to be construed as limiting the present invention, or any embodiments thereof, to anything stated or implied therein or inferred thereupon. By way of educational background, another aspect of the prior art generally useful to be aware of is that numerous magnetic properties of MTJMSD could not be understood due the lack of simulation and modelling method for microscopic MSDs at room temperature. The biggest challenge in advancing the MSD field is due to the lack of simulation and modeling tools and methods that may successfully predict or explain the microscopic phenomenon on MSDs. Existing strategies are either not feasible due to the complexity of MSD or just focus on a particular part of MSD and applicable for unrealistic environment (e.g., 0 K temperature).

In view of the foregoing, it is clear that these traditional techniques are not perfect and leave room for more optimal approaches.

### BRIEF DESCRIPTION OF THE DRAWINGS

The present invention is illustrated by way of example, and not by way of limitation, in the figures of the accompanying drawings and in which like reference numerals refer to similar elements and in which:

FIG. 1 is an illustration of an exemplary pillar shaped molecular spintronics device (MSD) on which simulation program is applied and various stages of the application of the simulation program, in accordance with an embodiment of the present invention. FIG. 1a-1b illustrate an exemplary trilayer ferromagnet-insulator-ferromagnet as the ferromagnet-insulator-ferromagnet is transformed in MSD by bonding magnetic molecules across the insulator. FIG. 1c illustrates an exemplary bonding magnetic molecule. FIG. 1d illustrates an exemplary ball and stick model representation of an experimental MSD in a Monte Carlo Simulation (MCS). FIG. 1e shows the interfacial atomic structure and critical parameters defining the properties of an exemplary magnetic tunnel junction-based molecular spintronics device (MTJMSD). FIG. if shows an Atomic Force Microscope (AFM) image of the cross junction shaped (magnetic tunnel junction) MTJ with exposed side edges. FIG. 1g illustrates an exemplary simulation of the cumulative effect of various defects present within the cross-junction area. FIG. 1h and FIG. 1i show 3D illustrations of experimentally studied exposed edge MTJ before and after molecular channel hosting. FIG. 1j-1k illustrate exemplary MSD designs and different molecules connected to ferromagnetic electrodes as potential device elements to be experimentally studied. FIG. 1m shows an exemplary 3D ball and stick model representation of magnetic tunnel junction-based MSDs (MTJMSD) from a Monte Carlo Simulation for MSD (MCSMSD);

FIG. 2 is an illustration of an exemplary input flow chart for configuring a 3D model of a molecular spintronics device (MSD) to be simulated by the MCSMSD program, in accordance with an embodiment of the present invention;

FIG. 3 is an illustration of an exemplary flow chart showing acceptance and rejection process of a newly created state based on a Metropolis algorithm, in accordance with an embodiment of the present invention;

FIG. 4 is an illustration of an exemplary functional layout of an exemplary MCSMSD, in accordance with an embodiment of the present invention;

FIG. 5 is an illustration of an exemplary flow chart showing a general structure of an exemplary MCSMSD program from start to end, in accordance with an embodiment of the present invention;

FIG. 6 is an illustration of an exemplary flow chart showing a general structure of an iterate.cpp application that is used for studying evolution of a desired MSD from a random state to equilibrium state for fixed value set of parameters, in accordance with an embodiment of the present invention;

FIG. 7 is an illustration of an exemplary flow chart showing a general structure of a Metropolis.cpp application that is used for studying a desired MSD for range of simulation parameters and storing all data in XML tree, in accordance with an embodiment of the present invention;

FIG. 8 is an illustration of an exemplary flow chart showing a general structure of a Heat.cpp application program in MCSMSD group of programs, in accordance with an embodiment of the present invention;

FIG. 9A is an illustration of an exemplary magnetic tunnel junction, FIG. 9B is an illustration of an exemplary magnetic molecule connected to metal atoms with spin, and FIG. 9C is an illustration of an exemplary result of an MCS program strategy, in accordance with an embodiment of the present invention;

FIG. 10 is a block diagram depicting an exemplary client/server system which may be used by an exemplary web-enabled/networked embodiment of the present invention.

Unless otherwise indicated illustrations in the figures are not necessarily drawn to scale.

### DETAILED DESCRIPTION OF SOME EMBODIMENTS

The present invention is best understood by reference to the detailed figures and description set forth herein.

Magnetic Tunnel Junction (MTJ): MTJ relates to some existing products and future memory devices in the semiconductor industry being perfected for commercialization (e.g., Magnetic Random Access Memory). In the disclosed software invention, MTJ is used as the example of devices on which the disclosed simulation program work.

Molecular Spintronics Devices (MSD): MSD is a targeting of the properties of molecules for making futuristic logic and memory devices. MSD represent a wide range of device architectures. In the context of the disclosed invention, MSD is used as the main device for which the disclosed simulation software works best. The disclosed simulation software discussed may not study every form.

Magnetic Tunnel Junction-based Molecular Spintronics Devices (MTJMSD): MTJMSD is the key word representing a class of MSD which is closest to industrial application. MTJMSD is also used in inventor's two recent patent applications. (Tyagi, P. Trenched Bottom Electrode and Liftoff based Molecular Devices. U.S. patent application Ser. No. 16/102,732. 2020. and follow up child patent which is in patent pending state.) The disclosed simulation focusses on Magnetic Tunnel Junction-based MSD (MTJMSD).

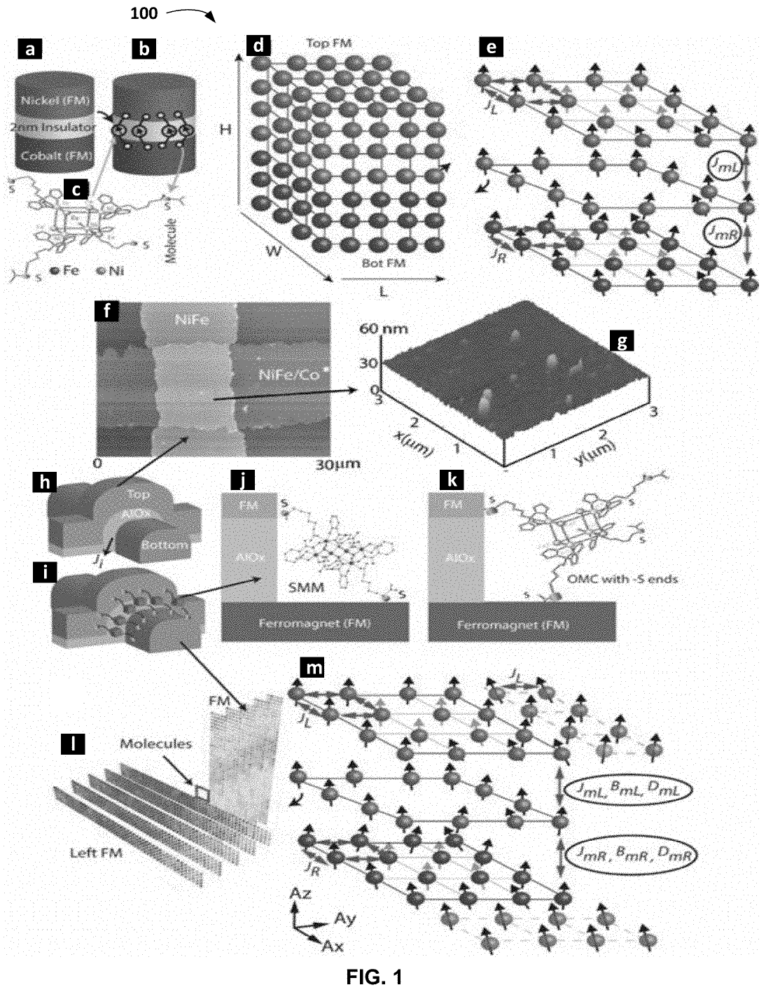

Monte Carlo Simulation (MCS): The MCS program may, referring to FIG. 1, study complex MSDs like cross junction shaped MSDs (f) and also consider practical limitations such as the presence of defects in the MSDs (g) by representing defects with a parameter (e.g., Ji) in the energy algorithm (h). The MCS program represent experimentally studied MSD designs and different molecules (i) connected to ferromagnetic electrodes (j) and (k).

Monte Carlo Simulation for MSD (MCSMSD): MCSMSD allow study of very large system involving magnetic molecules and magnetic electrodes. The methodology is based on setting up a master energy equation involving subsections based on experimentally relevant energy components. Each sub section represents a unique aspect of the (MSD) device. The methodology is highly versatile as it virtually covers a widest range of MSD possibilities. Moreover, a master energy equation may be further expanded by included additional phenomenon and mechanisms that may bring novel properties and unprecedented behavior that may be verified experimentally.

Embodiments of the invention are discussed below with reference to the Figures. However, those skilled in the art may readily appreciate that the detailed description given herein with respect to these figures is for explanatory purposes as the invention extends beyond these limited embodiments. For example, it should be appreciated that those skilled in the art may, in light of the teachings of the present invention, recognize a multiplicity of alternate and suitable approaches, depending upon the needs of the particular application, to implement the functionality of any given detail described herein, beyond the particular implementation choices in the following embodiments described and shown. That is, there are modifications and variations of the invention that are too numerous to be listed but that all fit within the scope of the invention. Also, singular words should be read as plural and vice versa and masculine as feminine and vice versa, where appropriate, and alternative embodiments do not necessarily imply that the two are mutually exclusive.

It is to be further understood that the present invention is not limited to the particular methodology, compounds, materials, manufacturing techniques, uses, and applications, described herein, as these may vary. It is also to be understood that the terminology used herein is used for the purpose of describing particular embodiments only, and is not intended to limit the scope of the present invention. It must be noted that as used herein and in the appended claims, the singular forms “a,” “an,” and “the” include the plural reference unless the context clearly dictates otherwise. Thus, for example, a reference to “an element” is a reference to one or more elements and includes equivalents thereof known to those skilled in the art. Similarly, for another example, a reference to “a step” or “a means” is a reference to one or more steps or means and may include sub-steps and subservient means. All conjunctions used are to be understood in the most inclusive sense possible. Thus, the word “or” should be understood as having the definition of a logical “or” rather than that of a logical “exclusive or” unless the context clearly necessitates otherwise. Structures described herein are to be understood also to refer to functional equivalents of such structures. Language that may be construed to express approximation should be so understood unless the context clearly dictates otherwise.

All words of approximation as used in the present disclosure and claims should be construed to mean “approximate,” rather than “perfect,” and may accordingly be employed as a meaningful modifier to any other word, specified parameter, quantity, quality, or concept. Words of approximation, include, yet are not limited to terms such as “substantial”, “nearly”, “almost”, “about”, “generally”, “largely”, “essentially”, “closely approximate”, etc.

As will be established in some detail below, it is well settled law, as early as 1939, that words of approximation are not indefinite in the claims even when such limits are not defined or specified in the specification.

For example, see Ex parte Mallory, 52 USPQ 297, 297 (Pat. Off. Bd. App. 1941) where the court said “The examiner has held that most of the claims are inaccurate because apparently the laminar film may not be entirely eliminated. The claims specify that the film is “substantially” eliminated and for the intended purpose, it is believed that the slight portion of the film which may remain is negligible. We are of the view, therefore, that the claims may be regarded as sufficiently accurate.”

Note that claims need only “reasonably apprise those skilled in the art” as to their scope to satisfy the definiteness requirement. See Energy Absorption Sys., Inc. v. Roadway Safety Servs., Inc., Civ. App. 96-1264, slip op. at 10 (Fed. Cir. Jul. 3, 1997) (unpublished) Hybridtech v. Monoclonal Antibodies, Inc., 802 F.2d 1367, 1385, 231 USPQ 81, 94 (Fed. Cir. 1986), cert. denied, 480 U.S. 947 (1987). In addition, the use of modifiers in the claim, like “generally” and “substantial,” does not by itself render the claims indefinite. See Seattle Box Co. v. Industrial Crating & Packing, Inc., 731 F.2d 818, 828-29, 221 USPQ 568, 575-76 (Fed. Cir. 1984).

Moreover, the ordinary and customary meaning of terms like “substantially” includes “reasonably close to: nearly, almost, about”, connoting a term of approximation. See In re Frye, Appeal No. 2009-006013, 94 USPQ2d 1072, 1077, 2010 WL 889747 (B.P.A.I. 2010) Depending on its usage, the word “substantially” may denote either language of approximation or language of magnitude. Deering Precision Instruments, L.L.C. v. Vector Distribution Sys., Inc., 347 F.3d 1314, 1323 (Fed. Cir. 2003) (recognizing the “dual ordinary meaning of th[e] term [“substantially”] as connoting a term of approximation or a term of magnitude”). Here, when referring to the “substantially halfway” limitation, the Specification uses the word “approximately” as a substitute for the word “substantially” (Fact 4). (Fact 4). The ordinary meaning of “substantially halfway” is thus reasonably close to or nearly at the midpoint between the forwardmost point of the upper or outsole and the rearwardmost point of the upper or outsole.

Similarly, the term ‘substantially’ is well recognized in case law to have the dual ordinary meaning of connoting a term of approximation or a term of magnitude. See Dana Corp. v. American Axle & Manufacturing, Inc., Civ. App. 04-1116, 2004 U.S. App. LEXIS 18265, *13-14 (Fed. Cir. Aug. 27, 2004) (unpublished). The term “substantially” is commonly used by claim drafters to indicate approximation. See Cordis Corp. v. Medtronic AVE Inc., 339 F.3d 1352, 1360 (Fed. Cir. 2003) (“The patents do not set out any numerical standard by which to determine whether the thickness of the wall surface is ‘substantially uniform.’ The term ‘substantially,’ as used in this context, denotes approximation. Thus, the walls must be of largely or approximately uniform thickness.”); see also Deering Precision Instruments, LLC v. Vector Distribution Sys., Inc., 347 F.3d 1314, 1322 (Fed. Cir. 2003); Epcon Gas Sys., Inc. v. Bauer Compressors, Inc., 279 F.3d 1022, 1031 (Fed. Cir. 2002). We find that the term “substantially” was used in just such a manner in the claims of the patents-in-suit: “substantially uniform wall thickness” denotes a wall thickness with approximate uniformity.

It should also be noted that such words of approximation as contemplated in the foregoing clearly limits the scope of claims such as saying ‘generally parallel’ such that the adverb ‘generally’ does not broaden the meaning of parallel. Accordingly, it is well settled that such words of approximation as contemplated in the foregoing (e.g., like the phrase ‘generally parallel’) envisions some amount of deviation from perfection (e.g., not exactly parallel), and that such words of approximation as contemplated in the foregoing are descriptive terms commonly used in patent claims to avoid a strict numerical boundary to the specified parameter. To the extent that the plain language of the claims relying on such words of approximation as contemplated in the foregoing are clear and uncontradicted by anything in the written description herein or the figures thereof, it is improper to rely upon the present written description, the figures, or the prosecution history to add limitations to any of the claim of the present invention with respect to such words of approximation as contemplated in the foregoing. That is, under such circumstances, relying on the written description and prosecution history to reject the ordinary and customary meanings of the words themselves is impermissible. See, for example, Liquid Dynamics Corp. v. Vaughan Co., 355 F.3d 1361, 69 USPQ2d 1595, 1600-01 (Fed. Cir. 2004). The plain language of phrase 2 requires a “substantial helical flow.” The term “substantial” is a meaningful modifier implying “approximate,” rather than “perfect.” In Cordis Corp. v. Medtronic AVE, Inc., 339 F.3d 1352, 1361 (Fed. Cir. 2003), the district court imposed a precise numeric constraint on the term “substantially uniform thickness.” We noted that the proper interpretation of this term was “of largely or approximately uniform thickness” unless something in the prosecution history imposed the “clear and unmistakable disclaimer” needed for narrowing beyond this simple-language interpretation. Id. In Anchor Wall Systems v. Rockwood Retaining Walls, Inc., 340 F.3d 1298, 1311 (Fed. Cir. 2003)” Id. at 1311. Similarly, the plain language of Claim 1 requires neither a perfectly helical flow nor a flow that returns precisely to the center after one rotation (a limitation that arises only as a logical consequence of requiring a perfectly helical flow).

The reader should appreciate that case law generally recognizes a dual ordinary meaning of such words of approximation, as contemplated in the foregoing, as connoting a term of approximation or a term of magnitude; e.g., see Deering Precision Instruments, L.L.C. v. Vector Distrib. Sys., Inc., 347 F.3d 1314, 68 USPQ2d 1716, 1721 (Fed. Cir. 2003), cert. denied, 124 S. Ct. 1426 (2004) where the court was asked to construe the meaning of the term “substantially” in a patent claim. Also see Epcon, 279 F.3d at 1031 (“The phrase ‘substantially constant’ denotes language of approximation, while the phrase ‘substantially below’ signifies language of magnitude, i.e., not insubstantial.”). Also, see, e.g., Epcon Gas Sys., Inc. v. Bauer Compressors, Inc., 279 F.3d 1022 (Fed. Cir. 2002) (construing the terms “substantially constant” and “substantially below”); Zodiac Pool Care, Inc. v. Hoffinger Indus., Inc., 206 F.3d 1408 (Fed. Cir. 2000) (construing the term “substantially inward”); York Prods., Inc. v. Cent. Tractor Farm & Family Ctr., 99 F.3d 1568 (Fed. Cir. 1996) (construing the term “substantially the entire height thereof”); Tex. Instruments Inc. v. Cypress Semiconductor Corp., 90 F.3d 1558 (Fed. Cir. 1996) (construing the term “substantially in the common plane”). In conducting their analysis, the court instructed to begin with the ordinary meaning of the claim terms to one of ordinary skill in the art. Prima Tek, 318 F.3d at 1148. Reference to dictionaries and the cases indicates that the term “substantially” has numerous ordinary meanings. As the district court stated, “substantially” may mean “significantly” or “considerably.” The term “substantially” may also mean “largely” or “essentially.” Webster's New 20th Century Dictionary 1817 (1983).

Words of approximation, as contemplated in the foregoing, may also be used in phrases establishing approximate ranges or limits, where the end points are inclusive and approximate, not perfect; e.g., see AK Steel Corp. v. Sollac, 344 F.3d 1234, 68 USPQ2d 1280, 1285 (Fed. Cir. 2003) where it where the court said [W]e conclude that the ordinary meaning of the phrase “up to about 10%” includes the “about 10%” endpoint. As pointed out by AK Steel, when an object of the preposition “up to” is nonnumeric, the most natural meaning is to exclude the object (e.g., painting the wall up to the door). On the other hand, as pointed out by Sollac, when the object is a numerical limit, the normal meaning is to include that upper numerical limit (e.g., counting up to ten, seating capacity for up to seven passengers). Because we have here a numerical limit—“about 10%”—the ordinary meaning is that that endpoint is included.

In the present specification and claims, a goal of employment of such words of approximation, as contemplated in the foregoing, is to avoid a strict numerical boundary to the modified specified parameter, as sanctioned by Pall Corp. v. Micron Separations, Inc., 66 F.3d 1211, 1217, 36 USPQ2d 1225, 1229 (Fed. Cir. 1995) where it states “It is well established that when the term “substantially” serves reasonably to describe the subject matter so that its scope would be understood by persons in the field of the invention, and to distinguish the claimed subject matter from the prior art, it is not indefinite.” Likewise see Verve LLC v. Crane Cams Inc., 311 F.3d 1116, 65 USPQ2d 1051, 1054 (Fed. Cir. 2002). Expressions such as “substantially” are used in patent documents when warranted by the nature of the invention, in order to accommodate the minor variations that may be appropriate to secure the invention. Such usage may well satisfy the charge to “particularly point out and distinctly claim” the invention, 35 U.S.C. § 112, and indeed may be necessary in order to provide the inventor with the benefit of his invention. In Andrew Corp. v. Gabriel Elecs. Inc., 847 F.2d 819, 821-22, 6 USPQ2d 2010, 2013 (Fed. Cir. 1988) the court explained that usages such as “substantially equal” and “closely approximate” may serve to describe the invention with precision appropriate to the technology and without intruding on the prior art. The court again explained in Ecolab Inc. v. Envirochem, Inc., 264 F.3d 1358, 1367, 60 USPQ2d 1173, 1179 (Fed. Cir. 2001) that “like the term ‘about,’ the term ‘substantially’ is a descriptive term commonly used in patent claims to ‘avoid a strict numerical boundary to the specified parameter, see Ecolab Inc. v. Envirochem Inc., 264 F.3d 1358, 60 USPQ2d 1173, 1179 (Fed. Cir. 2001) where the court found that the use of the term “substantially” to modify the term “uniform” does not render this phrase so unclear such that there is no means by which to ascertain the claim scope.

Similarly, other courts have noted that like the term “about,” the term “substantially” is a descriptive term commonly used in patent claims to “avoid a strict numerical boundary to the specified parameter.”; e.g., see Pall Corp. v. Micron Seps., 66 F.3d 1211, 1217, 36 USPQ2d 1225, 1229 (Fed. Cir. 1995); see, e.g., Andrew Corp. v. Gabriel Elecs. Inc., 847 F.2d 819, 821-22, 6 USPQ2d 2010, 2013 (Fed. Cir. 1988) (noting that terms such as “approach each other,” “close to,” “substantially equal,” and “closely approximate” are ubiquitously used in patent claims and that such usages, when serving reasonably to describe the claimed subject matter to those of skill in the field of the invention, and to distinguish the claimed subject matter from the prior art, have been accepted in patent examination and upheld by the courts). In this case, “substantially” avoids the strict 100% nonuniformity boundary.

Indeed, the foregoing sanctioning of such words of approximation, as contemplated in the foregoing, has been established as early as 1939, see Ex parte Mallory, 52 USPQ 297, 297 (Pat. Off. Bd. App. 1941) where, for example, the court said “the claims specify that the film is “substantially” eliminated and for the intended purpose, it is believed that the slight portion of the film which may remain is negligible. We are of the view, therefore, that the claims may be regarded as sufficiently accurate.” Similarly, In re Hutchison, 104 F.2d 829, 42 USPQ 90, 93 (C.C.P.A. 1939) the court said, “It is realized that “substantial distance” is a relative and somewhat indefinite term, or phrase, but terms and phrases of this character are not uncommon in patents in cases where, according to the art involved, the meaning may be determined with reasonable clearness.”

Hence, for at least the forgoing reason, Applicants submit that it is improper for any examiner to hold as indefinite any claims of the present patent that employ any words of approximation.

Unless defined otherwise, all technical and scientific terms used herein have the same meanings as commonly understood by one of ordinary skill in the art to which this invention belongs. Preferred methods, techniques, devices, and materials are described, although any methods, techniques, devices, or materials similar or equivalent to those described herein may be used in the practice or testing of the present invention. Structures described herein are to be understood also to refer to functional equivalents of such structures. The present invention will be described in detail below with reference to embodiments thereof as illustrated in the accompanying drawings.

References to a “device,” an “apparatus,” a “system,” etc., in the preamble of a claim should be construed broadly to mean “any structure meeting the claim terms” exempt for any specific structure(s)/type(s) that has/(have) been explicitly disavowed or excluded or admitted/implied as prior art in the present specification or incapable of enabling an object/aspect/goal of the invention. Furthermore, where the present specification discloses an object, aspect, function, goal, result, or advantage of the invention that a specific prior art structure and/or method step is similarly capable of performing yet in a very different way, the present invention disclosure is intended to and shall also implicitly include and cover additional corresponding alternative embodiments that are otherwise identical to that explicitly disclosed except that they exclude such prior art structure(s)/step(s), and shall accordingly be deemed as providing sufficient disclosure to support a corresponding negative limitation in a claim claiming such alternative embodiment(s), which exclude such very different prior art structure(s)/step(s) way(s).

From reading the present disclosure, other variations and modifications may be apparent to persons skilled in the art. Such variations and modifications may involve equivalent and other features which are already known in the art, and which may be used instead of or in addition to features already described herein.

Although Claims have been formulated in this Application to particular combinations of features, it should be understood that the scope of the disclosure of the present invention also includes any novel feature or any novel combination of features disclosed herein either explicitly or implicitly or any generalization thereof, whether or not it relates to the same invention as presently claimed in any Claim and whether or not it mitigates any or all of the same technical problems as does the present invention.

Features which are described in the context of separate embodiments may also be provided in combination in a single embodiment. Conversely, various features which are, for brevity, described in the context of a single embodiment, may also be provided separately or in any suitable subcombination. The Applicants hereby give notice that new Claims may be formulated to such features and/or combinations of such features during the prosecution of the present Application or of any further Application derived therefrom.

References to “one embodiment,” “an embodiment,” “example embodiment,” “various embodiments,” “some embodiments,” “embodiments of the invention,” etc., may indicate that the embodiment(s) of the invention so described may include a particular feature, structure, or characteristic, but not every possible embodiment of the invention necessarily includes the particular feature, structure, or characteristic. Further, repeated use of the phrase “in one embodiment,” or “in an exemplary embodiment,” “an embodiment,” do not necessarily refer to the same embodiment, although they may. Moreover, any use of phrases like “embodiments” in connection with “the invention” are never meant to characterize that all embodiments of the invention must include the particular feature, structure, or characteristic, and should instead be understood to mean “at least some embodiments of the invention” include the stated particular feature, structure, or characteristic.

References to “user”, or any similar term, as used herein, may mean a human or non-human user thereof. Moreover, “user”, or any similar term, as used herein, unless expressly stipulated otherwise, is contemplated to mean users at any stage of the usage process, to include, without limitation, direct user(s), intermediate user(s), indirect user(s), and end user(s). The meaning of “user”, or any similar term, as used herein, should not be otherwise inferred, or induced by any pattern(s) of description, embodiments, examples, or referenced prior-art that may (or may not) be provided in the present patent.

References to “end user”, or any similar term, as used herein, is generally intended to mean late-stage user(s) as opposed to early-stage user(s). Hence, it is contemplated that there may be a multiplicity of different types of “end user” near the end stage of the usage process. Where applicable, especially with respect to distribution channels of embodiments of the invention comprising consumed retail products/services thereof (as opposed to sellers/vendors or Original Equipment Manufacturers), examples of an “end user” may include, without limitation, a “consumer”, “buyer”, “customer”, “purchaser”, “shopper”, “enjoyer”, “viewer”, or individual person or non-human thing benefiting in any way, directly or indirectly, from use of or interaction, with some aspect of the present invention.

In some situations, some embodiments of the present invention may provide beneficial usage to more than one stage or type of usage in the foregoing usage process. In such cases where multiple embodiments targeting various stages of the usage process are described, references to “end user”, or any similar term, as used therein, are generally intended to not include the user that is the furthest removed, in the foregoing usage process, from the final user therein of an embodiment of the present invention.

Where applicable, especially with respect to retail distribution channels of embodiments of the invention, intermediate user(s) may include, without limitation, any individual person or non-human thing benefiting in any way, directly or indirectly, from use of, or interaction with, some aspect of the present invention with respect to selling, vending, Original Equipment Manufacturing, marketing, merchandising, distributing, service providing, and the like thereof.

References to “person”, “individual”, “human”, “a party”, “animal”, “creature”, or any similar term, as used herein, even if the context or particular embodiment implies living user, maker, or participant, it should be understood that such characterizations are sole by way of example, and not limitation, in that it is contemplated that any such usage, making, or participation by a living entity in connection with making, using, and/or participating, in any way, with embodiments of the present invention may be substituted by such similar performed by a suitably configured non-living entity, to include, without limitation, automated machines, robots, humanoids, computational systems, information processing systems, artificially intelligent systems, and the like. It is further contemplated that those skilled in the art may readily recognize the practical situations where such living makers, users, and/or participants with embodiments of the present invention may be in whole, or in part, replaced with such non-living makers, users, and/or participants with embodiments of the present invention. Likewise, when those skilled in the art identify such practical situations where such living makers, users, and/or participants with embodiments of the present invention may be in whole, or in part, replaced with such non-living makers, it may be readily apparent in light of the teachings of the present invention how to adapt the described embodiments to be suitable for such non-living makers, users, and/or participants with embodiments of the present invention. Thus, the invention is thus to also cover all such modifications, equivalents, and alternatives falling within the spirit and scope of such adaptations and modifications, at least in part, for such non-living entities.

Headings provided herein are for convenience and are not to be taken as limiting the disclosure in any way.

The enumerated listing of items does not imply that any or all of the items are mutually exclusive, unless expressly specified otherwise.

It is understood that the use of specific component, device and/or parameter names are for example only and not meant to imply any limitations on the invention. The invention may thus be implemented with different nomenclature/terminology utilized to describe the mechanisms/units/structures/components/devices/parameters herein, without limitation. Each term utilized herein is to be given its broadest interpretation given the context in which that term is utilized.

Terminology. The following paragraphs provide definitions and/or context for terms found in this disclosure (including the appended claims):

“Comprising” And “contain” and variations of them—Such terms are open-ended and mean “including but not limited to”. When employed in the appended claims, this term does not foreclose additional structure or steps. Consider a claim that recites: “A memory controller comprising a system cache . . . .” Such a claim does not foreclose the memory controller from including additional components (e.g., a memory channel unit, a switch).

“Configured To.” Various units, circuits, or other components may be described or claimed as “configured to” perform a task or tasks. In such contexts, “configured to” or “operable for” is used to connote structure by indicating that the mechanisms/units/circuits/components include structure (e.g., circuitry and/or mechanisms) that performs the task or tasks during operation. As such, the mechanisms/unit/circuit/component may be said to be configured to (or be operable) for perform(ing) the task even when the specified mechanisms/unit/circuit/component is not currently operational (e.g., is not on). The mechanisms/units/circuits/components used with the “configured to” or “operable for” language include hardware—for example, mechanisms, structures, electronics, circuits, memory storing program instructions executable to implement the operation, etc. Reciting that a mechanism/unit/circuit/component is “configured to” or “operable for” perform(ing) one or more tasks is expressly intended not to invoke 35 U.S.C. sctn.112, sixth paragraph, for that mechanism/unit/circuit/component. “Configured to” may also include adapting a manufacturing process to fabricate devices or components that are adapted to implement or perform one or more tasks.

“Based On.” As used herein, this term is used to describe one or more factors that affect a determination. This term does not foreclose additional factors that may affect a determination. That is, a determination may be solely based on those factors or based, at least in part, on those factors. Consider the phrase “determine A based on B.” While B may be a factor that affects the determination of A, such a phrase does not foreclose the determination of A from also being based on C. In other instances, A may be determined based solely on B.

The terms “a”, “an” and “the” mean “one or more”, unless expressly specified otherwise.

All terms of exemplary language (e.g., including, without limitation, “such as”, “like”, “for example”, “for instance”, “similar to”, etc.) are not exclusive of any other, potentially, unrelated, types of examples; thus, implicitly mean “by way of example, and not limitation . . . ”, unless expressly specified otherwise.

Unless otherwise indicated, all numbers expressing conditions, concentrations, dimensions, and so forth used in the specification and claims are to be understood as being modified in all instances by the term “about.” Accordingly, unless indicated to the contrary, the numerical parameters set forth in the following specification and attached claims are approximations that may vary depending at least upon a specific analytical technique.

The term “comprising,” which is synonymous with “including,” “containing,” or “characterized by” is inclusive or open-ended and does not exclude additional, unrecited elements or method steps. “Comprising” is a term of art used in claim language which means that the named claim elements are essential, but other claim elements may be added and still form a construct within the scope of the claim.

As used herein, the phase “consisting of” excludes any element, step, or ingredient not specified in the claim. When the phrase “consists of” (or variations thereof) appears in a clause of the body of a claim, rather than immediately following the preamble, it limits only the element set forth in that clause; other elements are not excluded from the claim as a whole. As used herein, the phase “consisting essentially of” and “consisting of” limits the scope of a claim to the specified elements or method steps, plus those that do not materially affect the basis and novel characteristic(s) of the claimed subject matter (see Norian Corp. v Stryker Corp., 363 F.3d 1321, 1331-32, 70 USPQ2d 1508, Fed. Cir. 2004). Moreover, for any claim of the present invention which claims an embodiment “consisting essentially of” or “consisting of” a certain set of elements of any herein described embodiment it shall be understood as obvious by those skilled in the art that the present invention also covers all possible varying scope variants of any described embodiment(s) that are each exclusively (i.e., “consisting essentially of”) functional subsets or functional combination thereof such that each of these plurality of exclusive varying scope variants each consists essentially of any functional subset(s) and/or functional combination(s) of any set of elements of any described embodiment(s) to the exclusion of any others not set forth therein. That is, it is contemplated that it may be obvious to those skilled how to create a multiplicity of alternate embodiments of the present invention that simply consisting essentially of a certain functional combination of elements of any described embodiment(s) to the exclusion of any others not set forth therein, and the invention thus covers all such exclusive embodiments as if they were each described herein.

With respect to the terms “comprising,” “consisting of,” and “consisting essentially of,” where one of these three terms is used herein, the disclosed and claimed subject matter may include the use of either of the other two terms. Thus, in some embodiments not otherwise explicitly recited, any instance of “comprising” may be replaced by “consisting of” or, alternatively, by “consisting essentially of”, and thus, for the purposes of claim support and construction for “consisting of” format claims, such replacements operate to create yet other alternative embodiments “consisting essentially of” only the elements recited in the original “comprising” embodiment to the exclusion of all other elements.

Moreover, any claim limitation phrased in functional limitation terms covered by 35 USC § 112(6) (post AIA 112(f)) which has a preamble invoking the closed terms “consisting of,” or “consisting essentially of,” should be understood to mean that the corresponding structure(s) disclosed herein define the exact metes and bounds of what the so claimed invention embodiment(s) consists of, or consisting essentially of, to the exclusion of any other elements which do not materially affect the intended purpose of the so claimed embodiment(s).

Devices or system modules that are in at least general communication with each other need not be in continuous communication with each other, unless expressly specified otherwise. In addition, devices or system modules that are in at least general communication with each other may communicate directly or indirectly through one or more intermediaries. Moreover, it is understood that any system components described or named in any embodiment or claimed herein may be grouped or sub-grouped (and accordingly implicitly renamed) in any combination or sub-combination as those skilled in the art may imagine as suitable for the particular application, and still be within the scope and spirit of the claimed embodiments of the present invention. For an example of what this means, if the invention was a controller of a motor and a valve and the embodiments and claims articulated those components as being separately grouped and connected, applying the foregoing would mean that such an invention and claims would also implicitly cover the valve being grouped inside the motor and the controller being a remote controller with no direct physical connection to the motor or internalized valve, as such the claimed invention is contemplated to cover all ways of grouping and/or adding of intermediate components or systems that still substantially achieve the intended result of the invention.

A description of an embodiment with several components in communication with each other does not imply that all such components are required. On the contrary a variety of optional components is described to illustrate the wide variety of possible embodiments of the present invention.

As is well known to those skilled in the art many careful considerations and compromises typically must be made when designing for the optimal manufacture of a commercial implementation any system, and in particular, the embodiments of the present invention. A commercial implementation in accordance with the spirit and teachings of the present invention may configured according to the needs of the particular application, whereby any aspect(s), feature(s), function(s), result(s), component(s), approach(es), or step(s) of the teachings related to any described embodiment of the present invention may be suitably omitted, included, adapted, mixed and matched, or improved and/or optimized by those skilled in the art, using their average skills and known techniques, to achieve the desired implementation that addresses the needs of the particular application.

In the following description and claims, the terms “coupled” and “connected,” along with their derivatives, may be used. It should be understood that these terms are not intended as synonyms for each other. Rather, in particular embodiments, “connected” may be used to indicate that two or more elements are in direct physical or electrical contact with each other. “Coupled” may mean that two or more elements are in direct physical or electrical contact. However, “coupled” may also mean that two or more elements are not in direct contact with each other, but yet still cooperate or interact with each other.

It is to be understood that any exact measurements/dimensions or particular construction materials indicated herein are solely provided as examples of suitable configurations and are not intended to be limiting in any way. Depending on the needs of the particular application, those skilled in the art may readily recognize, in light of the following teachings, a multiplicity of suitable alternative implementation details.

A “computer” may refer to one or more apparatus and/or one or more systems that are capable of accepting a structured input, processing the structured input according to prescribed rules, and producing results of the processing as output. Examples of a computer may include: a computer; a stationary and/or portable computer; a computer having a single processor, multiple processors, or multi-core processors, which may operate in parallel and/or not in parallel; a general purpose computer; a supercomputer; a mainframe; a super mini-computer; a mini-computer; a workstation; a micro-computer; a server; a client; an interactive television; a web appliance; a telecommunications device with internet access; a hybrid combination of a computer and an interactive television; a portable computer; a tablet personal computer (PC); a personal digital assistant (PDA); a portable telephone; a smartphone, an application-specific hardware to emulate a computer and/or software, such as, for example, a digital signal processor (DSP), a field-programmable gate array (FPGA), an application specific integrated circuit (ASIC), an application specific instruction-set processor (ASIP), a chip, chips, a system on a chip, or a chip set; a data acquisition device; an optical computer; a quantum computer; a biological computer; and generally, an apparatus that may accept data, process data according to one or more stored software programs, generate results, and typically include input, output, storage, arithmetic, logic, and control units.

Those of skill in the art may appreciate that where appropriate, some embodiments of the disclosure may be practiced in network computing environments with many types of computer system configurations, including personal computers, hand-held devices, multi-processor systems, microprocessor-based or programmable consumer electronics, network PCs, minicomputers, mainframe computers, and the like. Where appropriate, embodiments may also be practiced in distributed computing environments where tasks are performed by local and remote processing devices that are linked (either by hardwired links, wireless links, or by a combination thereof) through a communications network. In a distributed computing environment, program modules may be located in both local and remote memory storage devices.

“Software” may refer to prescribed rules to operate a computer. Examples of software may include: code segments in one or more computer-readable languages; graphical and or/textual instructions; applets; pre-compiled code; interpreted code; compiled code; and computer programs.

The example embodiments described herein may be implemented in an operating environment comprising computer-executable instructions (e.g., software) installed on a computer, in hardware, or in a combination of software and hardware. The computer-executable instructions may be written in a computer programming language or may be embodied in firmware logic. If written in a programming language conforming to a recognized standard, such instructions may be executed on a variety of hardware platforms and for interfaces to a variety of operating systems. Although not limited thereto, computer software program code for carrying out operations for aspects of the present invention may be written in any combination of one or more suitable programming languages, including an object oriented programming languages and/or conventional procedural programming languages, and/or programming languages such as, for example, Hypertext Markup Language (HTML), Dynamic HTML, Extensible Markup Language (XML), Extensible Stylesheet Language (XSL), Document Style Semantics and Specification Language (DSSSL), Cascading Style Sheets (CSS), Synchronized Multimedia Integration Language (SMIL), Wireless Markup Language (WML), Java™, Jini™, C, C++, Smalltalk, Perl, UNIX Shell, Visual Basic or Visual Basic Script, Virtual Reality Markup Language (VRML), ColdFusion™ or other compilers, assemblers, interpreters or other computer languages or platforms.

Computer program code for carrying out operations for aspects of the present invention may be written in any combination of one or more programming languages, including an object-oriented programming language such as Java, Smalltalk, C++, or the like and conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

A network is a collection of links and nodes (e.g., multiple computers and/or other devices connected together) arranged so that information may be passed from one part of the network to another over multiple links and through various nodes. Examples of networks include the Internet, the public switched telephone network, the global Telex network, computer networks (e.g., an intranet, an extranet, a local-area network, or a wide-area network), wired networks, and wireless networks.

The Internet is a worldwide network of computers and computer networks arranged to allow the easy and robust exchange of information between computer users. Hundreds of millions of people around the world have access to computers connected to the Internet via Internet Service Providers (ISPs). Content providers (e.g., website owners or operators) place multimedia information (e.g., text, graphics, audio, video, animation, and other forms of data) at specific locations on the Internet referred to as webpages. Websites comprise a collection of connected, or otherwise related, webpages. The combination of all the websites and their corresponding webpages on the Internet is generally known as the World Wide Web (WWW) or simply the Web.

Aspects of the present invention are described below with reference to flowchart illustrations and/or block diagrams of methods, apparatus (systems) and computer program products according to embodiments of the invention. It may be understood that each block of the flowchart illustrations and/or block diagrams, and combinations of blocks in the flowchart illustrations and/or block diagrams, may be implemented by computer program instructions. These computer program instructions may be provided to a processor of a general-purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

The flowchart and block diagrams in the figures illustrate the architecture, functionality, and operation of possible implementations of systems, methods, and computer program products according to various embodiments. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown by way of example, and not limitation, in succession may, in fact, be executed substantially concurrently, or the blocks may sometimes be executed in the reverse order, depending upon the functionality involved. It may also be noted that each block of the block diagrams and/or flowchart illustration, and combinations of blocks in the block diagrams and/or flowchart illustration, may be implemented by special purpose hardware-based systems that perform the specified functions or acts, or combinations of special purpose hardware and computer instructions.

These computer program instructions may also be stored in a computer readable medium that may direct a computer, other programmable data processing apparatus, or other devices to function in a particular manner, such that the instructions stored in the computer readable medium produce an article of manufacture including instructions which implement the function/act specified in the flowchart and/or block diagram block or blocks.

Further, although process steps, method steps, algorithms or the like may be described in a sequential order, such processes, methods, and algorithms may be configured to work in alternate orders. In other words, any sequence or order of steps that may be described does not necessarily indicate a requirement that the steps be performed in that order. The steps of processes described herein may be performed in any order practical. Further, some steps may be performed simultaneously.

It may be readily apparent that the various methods and algorithms described herein may be implemented by, e.g., appropriately programmed general purpose computers and computing devices. Typically, a processor (e.g., a microprocessor) may receive instructions from a memory or like device, and execute those instructions, thereby performing a process defined by those instructions. Further, programs that implement such methods and algorithms may be stored and transmitted using a variety of known media.

When a single device or article is described herein, it may be readily apparent that more than one device/article (whether or not they cooperate) may be used in place of a single device/article. Similarly, where more than one device or article is described herein (whether or not they cooperate), it may be readily apparent that a single device/article may be used in place of the more than one device or article.

The functionality and/or the features of a device may be alternatively embodied by one or more other devices which are not explicitly described as having such functionality/features. Thus, other embodiments of the present invention need not include the device itself.

The term “computer-readable medium” as used herein refers to any medium that participates in providing data (e.g., instructions) which may be read by a computer, a processor or a like device. Such a medium may take many forms, including but not limited to, non-volatile media, volatile media, and transmission media. Non-volatile media include, for example, optical or magnetic disks and other persistent memory. Volatile media include dynamic random-access memory (DRAM), which typically constitutes the main memory. Transmission media include coaxial cables, copper wire and fiber optics, including the wires that comprise a system bus coupled to the processor. Transmission media may include or convey acoustic waves, light waves, and electromagnetic emissions, such as those generated during radio frequency (RF) and infrared (IR) data communications. Common forms of computer-readable media include, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, an EPROM, a FLASH-EEPROM, removable media, flash memory, a “memory stick”, any other memory chip or cartridge, a carrier wave as described hereinafter, or any other medium from which a computer may read.

Various forms of computer readable media may be involved in carrying sequences of instructions to a processor. For example, sequences of instruction (i) may be delivered from RAM to a processor, (ii) may be carried over a wireless transmission medium, and/or (iii) may be formatted according to numerous formats, standards, or protocols, such as Bluetooth, TDMA, CDMA, 3G.

Where databases are described, it may be understood by one of ordinary skill in the art that (i) alternative database structures to those described may be readily employed, (ii) other memory structures besides databases may be readily employed. Any schematic illustrations and accompanying descriptions of any sample databases presented herein are exemplary arrangements for stored representations of information. Any number of other arrangements may be employed besides those suggested by the tables shown. Similarly, any illustrated entries of the databases represent exemplary information only; those skilled in the art may understand that the number and content of the entries may be different from those illustrated herein. Further, despite any depiction of the databases as tables, an object-based model could be used to store and manipulate the data types of the present invention and likewise, object methods or behaviors may be used to implement the processes of the present invention.

A “computer system” may refer to a system having one or more computers, where each computer may include a computer-readable medium embodying software to operate the computer or one or more of its components. Examples of a computer system may include: a distributed computer system for processing information via computer systems linked by a network; two or more computer systems connected together via a network for transmitting and/or receiving information between the computer systems; a computer system including two or more processors within a single computer; and one or more apparatuses and/or one or more systems that may accept data, may process data in accordance with one or more stored software programs, may generate results, and typically may include input, output, storage, arithmetic, logic, and control units.

A “network” may refer to a number of computers and associated devices that may be connected by communication facilities. A network may involve permanent connections such as cables or temporary connections such as those made through telephone or other communication links. A network may further include hard-wired connections (e.g., coaxial cable, twisted pair, optical fiber, waveguides, etc.) and/or wireless connections (e.g., radio frequency waveforms, free-space optical waveforms, acoustic waveforms, etc.). Examples of a network may include: an internet, such as the Internet; an intranet; a local area network (LAN); a wide area network (WAN); and a combination of networks, such as an internet and an intranet.

As used herein, the “client-side” application should be broadly construed to refer to an application, a page associated with that application, or some other resource or function invoked by a client-side request to the application. A “browser” as used herein is not intended to refer to any specific browser (e.g., Internet Explorer, Safari, FireFox, or the like), but should be broadly construed to refer to any client-side rendering engine that may access and display Internet-accessible resources. A “rich” client typically refers to a non-HTTP based client-side application, such as an SSH or CFIS client. Further, while typically the client-server interactions occur using HTTP, this is not a limitation either. The client server interaction may be formatted to conform to the Simple Object Access Protocol (SOAP) and travel over HTTP (over the public Internet), FTP, or any other reliable transport mechanism (such as IBM® MQSeries® technologies and CORBA, for transport over an enterprise intranet) may be used. Any application or functionality described herein may be implemented as native code, by providing hooks into another application, by facilitating use of the mechanism as a plug-in, by linking to the mechanism, and the like.

Exemplary networks may operate with any of a number of protocols, such as Internet protocol (IP), asynchronous transfer mode (ATM), and/or synchronous optical network (SONET), user datagram protocol (UDP), IEEE 802.x, etc.

Embodiments of the present invention may include apparatuses for performing the operations disclosed herein. An apparatus may be specially constructed for the desired purposes, or it may comprise a general-purpose device selectively activated or reconfigured by a program stored in the device.

Embodiments of the invention may also be implemented in one or a combination of hardware, firmware, and software. They may be implemented as instructions stored on a machine-readable medium, which may be read and executed by a computing platform to perform the operations described herein.

More specifically, as may be appreciated by one skilled in the art, aspects of the present invention may be embodied as a system, method, or computer program product. Accordingly, aspects of the present invention may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects of the present invention may take the form of a computer program product embodied in one or more computer readable medium(s) having computer readable program code embodied thereon.

In the following description and claims, the terms “computer program medium” and “computer readable medium” may be used to generally refer to media such as, but not limited to, removable storage drives, a hard disk installed in hard disk drive, and the like. These computer program products may provide software to a computer system. Embodiments of the invention may be directed to such computer program products.

An algorithm is here, and generally, considered to be a self-consistent sequence of acts or operations leading to a desired result. These include physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like. It should be understood, however, that all of these and similar terms are to be associated with the appropriate physical quantities and are merely convenient labels applied to these quantities.

Unless specifically stated otherwise, and as may be apparent from the following description and claims, it should be appreciated that throughout the specification descriptions utilizing terms such as “processing,” “computing,” “calculating,” “determining,” or the like, refer to the action and/or processes of a computer or computing system, or similar electronic computing device, that manipulate and/or transform data represented as physical, such as electronic, quantities within the computing system's registers and/or memories into other data similarly represented as physical quantities within the computing system's memories, registers or other such information storage, transmission or display devices.

Additionally, the phrase “configured to” or “operable for” may include generic structure (e.g., generic circuitry) that is manipulated by software and/or firmware (e.g., an FPGA or a general-purpose processor executing software) to operate in a manner that is capable of performing the task(s) at issue. “Configured to” may also include adapting a manufacturing process (e.g., a semiconductor fabrication facility) to fabricate devices (e.g., integrated circuits) that are adapted to implement or perform one or more tasks.

In a similar manner, the term “processor” may refer to any device or portion of a device that processes electronic data from registers and/or memory to transform that electronic data into other electronic data that may be stored in registers and/or memory. A “computing platform” may comprise one or more processors.

Embodiments within the scope of the present disclosure may also include tangible and/or non-transitory computer-readable storage media for carrying or having computer-executable instructions or data structures stored thereon. Such non-transitory computer-readable storage media may be any available media that may be accessed by a general purpose or special purpose computer, including the functional design of any special purpose processor as discussed above. By way of example, and not limitation, such non-transitory computer-readable media may include RAM, ROM, EEPROM, CD-ROM or other optical disk storage, magnetic disk storage or other magnetic storage devices, or any other medium which may be used to carry or store desired program code means in the form of computer-executable instructions, data structures, or processor chip design. When information is transferred or provided over a network or another communications connection (either hardwired, wireless, or combination thereof) to a computer, the computer properly views the connection as a computer-readable medium. Thus, any such connection is properly termed a computer-readable medium. Combinations of the above should also be included within the scope of the computer-readable media.

While a non-transitory computer readable medium includes, but is not limited to, a hard drive, compact disc, flash memory, volatile memory, random access memory, magnetic memory, optical memory, semiconductor-based memory, phase change memory, optical memory, periodically refreshed memory, and the like; the non-transitory computer readable medium, however, does not include a pure transitory signal per se; i.e., where the medium itself is transitory.

In some embodiments of the present invention and variations thereof, relate to systems and methods for simulating the spatial and temporal magnetic properties of configurable nanoscale magnetic molecules connected to two configurable ferromagnetic electrodes at configurable thermal energies and magnetic fields.

In one embodiment of the present invention, mass-producible and robust Molecular Spintronics Device (MSD) may revolutionize memory and logic devices to produce the next generation of computers. MSDs are also explored worldwide for the potential application in quantum computers to harness the quantum properties of molecules. MSD may be a testbed for producing novel materials where molecules serve as a catalyst to activate spin filtering-like phenomenon and impact the connected two ferromagnets or metal electrodes (FIG. 1a-c). Fabrication and systematically understanding MSD are two major hurdles in advancing this field. Tyagi et al. proposed a Magnetic tunnel junction-based molecular spintronics device (MTJMSD) to overcome fabrication difficulty and observed a number of unprecedented phenomena. Numerous magnetic properties of MTJMSD may be understood with a simulation and modelling method for microscopic MSDs at room temperature. The disclosed simulation and modeling tools and methods may predict or explain the microscopic phenomenon on MSDs. A Monte Carlo Simulation for MSD (MCSMSD) may focus on a particular part of MSD and applicable for a wide range of environments (e.g., low to very high temperature). The main components of an exemplary MSD are two magnetic electrodes, molecules, and insulating spacer as shown in FIG. 1c and FIG. 1i-j. MCSMSD account for interdependency of different MSD's components in computing physical properties.

Function of the MCSMSD Program:

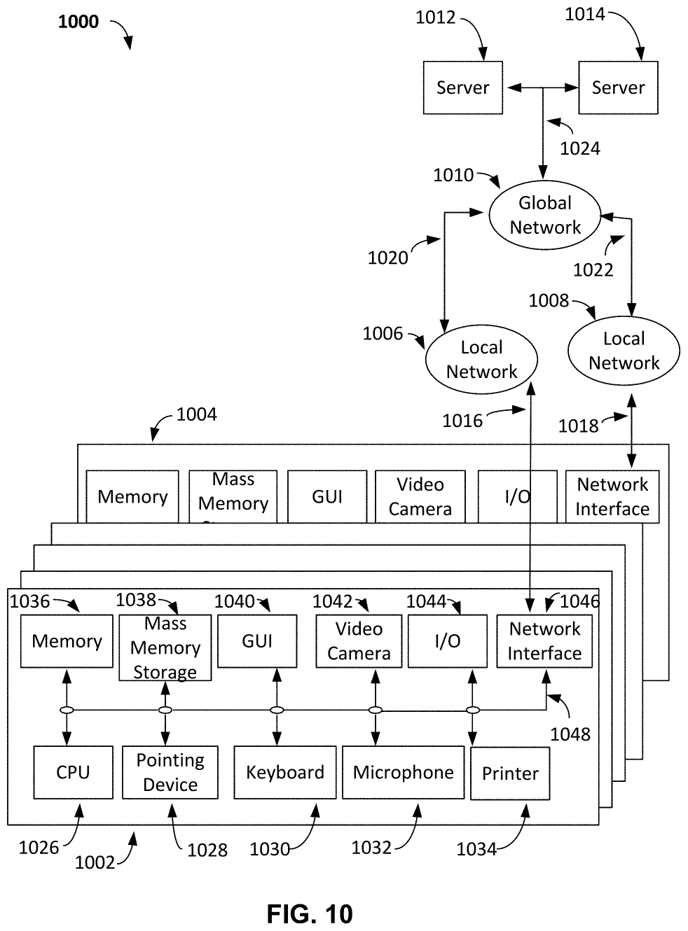

In some embodiment, a method of simulating the properties of complex MSDs may include, but not limited to, an integrated C++ computer program to conduct Monte Carlo simulations (MCS). The MCSMSD simulation program has been tested on experimentally produced MTJMSD. The disclosed MCS method may represent many forms of MSDs, magnetic tunnel junctions, and cases of nanoscale magnetic materials connected to different types of metal leads, otherwise not possible with other methods. The MCSMSD program may produce an atomic model analogous to MTJMSD or MSD to help visualize the impact of molecules and nanostructure on individual atoms of electrode materials at different temperatures and magnetic fields. The approach utilizes physics principles rooted in experimental studies. Another major feature of the approach is that one may use regular computers (e.g., FIG. 10) without needing supercomputers to study transition elements and molecules.

After setting up a representative atomic model, material parameters specific to metal electrodes and molecules are varied to investigate the wide range of possible equilibrium properties. Subsequently, a combination of stimulation parameters is compared to determine the desired simulation results in agreement with the experimental observation. The disclosed approach is just the opposite of a conventional DFT approach, where simulation and modeling are based on specific structures and types of electrode atoms involved in the study.

The MCSMSD program functionality and methodology by way of two examples of MSD structures for which the disclosed MCSMSD was tested. Experimentally, the MTJMSDs on which this simulation program was applied satisfactorily. Results from the MCSMSD program explained several experimentally observed phenomena that were impossible otherwise. The studies are discussed in the references mentioned in [6-12].

The first example where the rudimentary form of disclosed MCSMSD program was initially tested is pillar-shaped MTJMSD (FIG. 1a-b). To experimentally produce MTJMSD, an exposed edge magnetic tunnel junction (MTJ) (FIG. 1a) is produced first. The MTJ is a three-layer structure where two ferromagnetic (F.M.) electrodes are separated by a robust ˜2 nm insulating spacer (FIG. 1a). Subsequently, a cylindrical or rectangular prism-shaped MTJ allowed molecules of interest to form a bridge across the insulating spacer (FIG. 1B). The molecule used in this study was octametallic molecular clusters (OMC) with four ropes-like sections connected to the molecule core. An end of each rope-like molecule possessed sulfur atoms to serve as glue to form a bond with desired metal layers of the tunnel junction. The OMC provided insights about the typical structures of molecules to be used in MSD or MTJMSD that are to be studied by the disclosed MCSMSD program. In the experimental MSD research, such molecules are expected to be used regularly. Simulating the properties of magnetic molecule alone is generally a difficult problem and require Density functional theory (DFT) based simulation approaches. The OMC using DFT-like simulation approaches did not produce any insights or knowledge on how an actual OMC-based MTJMSD behaved.

Basis of MCSMSD Conceptualization:

A very pertinent aspect to note about a magnetic molecule is that it may have a net spin irrespective of structural complexity. Hence, replacing the molecule core with an equivalent single atom with a net spin may provide a practical way to treat complex magnetic molecules in simulations. This is the foundational assumption that enabled the development of the disclosed MCSMSD program.

Two critical issues in MSD field are (i) difficulty in experimentally connecting magnetic molecules to the magnetic electrode and (ii) understanding the intriguing properties when magnetic molecules are attached to the ferromagnetic electrodes. Furthermore, molecules are known to be only mass production nanostructures designed to possess a vast range of magnetic, optical, thermal, and electrical properties [15, 16]. Some experimentally observed molecule-based device properties were satisfactorily understood using generic equations and models applicable for typical nanostructures and insulators. A list of generic equations relevant to any nanostructure for understanding the properties of molecules connected to non-magnetic metal electrodes is provided. The application of generic nanostructure equation for studying molecular devices without delving into molecule-specific details or molecule structure provided the thoughts for making the Monte Carlo simulations (MCS) simulation program to study MSD. MCS is basically an approach that is based on two steps: (a) Find an energy equation specific to a material system, (b) utilize this equation to accept or reject randomly created new states at each atom of the system, (c) after millions of iterations or trial MCS select combination of states on each atom that produce least amount of energy. Essentially, one may keep changing the value of material specific parameters and use MCS method to find stable state of the whole system by finding stable state at each atom involved in the system. The MCS approach is also applicable for varying external factor such as temperature and magnetic field by altering related term in the master energy equation to find stable state of system under different environment.

So far, the MCS approach has been applied separately with different components of MSD in unrelated contexts. The MCS was also applied on full microscopic devices. MCS was effective in understanding atoms and molecules length scale. Temperature-dependent properties of molecule like magnetic nanostructures were demonstrated successfully. Literature also shows MCS may be applied to different shapes and forms of molecules, including the Single Molecule magnets to be used in MTJMSDs.

In some embodiment, the disclosed invention provides an MCS method to study and design MSD involving physics of molecule scale magnetic elements and physics of microscopic scale magnetic tunnel junctions. The application area of disclosed MCS simulation program for MSD is discussed by the following examples of two specific MSDs and their components.

The equilibrium properties of an MSD may ultimately depend on how a magnetic molecule(s) is connected with the two metal electrodes (generally magnetic). Molecules may also be designed to form extremely weak to extremely strong bonds with desired metal leads or films. In the present example, octa metallic molecular cluster (OMC) possessed four tethers like molecule chains (FIG. 1k) to help connect molecules to metal electrodes. How strongly a chain may latch onto metal lead may depend on what chemical or functional group is present at the end of each chain. In the particular example of OMCs, each of the four chains is terminated by the thiol (—S) group. The merit of the thiol group is that it makes the strongest form of the chemical bond with Nickel like magnetic material and represents the strongest metal-molecule coupling in the field of MSD. On the other hand, if—S was absent, OMC could make no coupling or weak coupling with metal leads of the MSDs (FIG. 1k). Hence, a paramagnetic molecule's center connected to two metal electrodes along the side edges may produce a vast range of possibilities based on how molecule latch on to metal electrodes. A very pertinent aspect in the context of the MCS program discussed here is that condensed matter physics provides robust and well-tested equations to represent strong to weak magnetic interactions between two entities. Generic interaction energy terms may be applied for molecule and films coupling and may be part of the master energy equation. The strongest magnetic coupling between molecules and the magnetic film is Heisenberg exchange coupling. The intermediate level of coupling is known as biquadratic coupling and is defined by an equation. A very helpful practical aspect for the present embodiment is that the biquadratic coupling equation is the same for molecules [25] and multilayer structures. The weakest form of magnetic coupling is long-range dipolar exchange coupling, represented by the well-defined equation for Monte Carlo simulations. Hence, in the MCS simulation method, magnetic molecule-ferromagnetic electrode coupling with the help of well-known physics energy equations is defined.

MCSMSD for Simulating MSD:

The MCS program has been developed over the years (e.g., >10 years) and kept improving by applying on experimentally studied MSDs. Referring to FIG. 1, an initial application was limited to pillar shaped MTJMSD (FIG. 1B). The initial form of the MCS program created a rectangular pillar-shaped atomic model to represent pillar-shaped MSD. The devices are referred to as magnetic tunnel junction (MTJ) based MSD (MTJMSD) (FIG. 1d). In the model, top and bottom ferromagnet (FM) electrodes were represented by a 3D lattice with the ball and stick model with configurable height (H), width (W), and length (L) dimensions. Variation in H, W, and L is done in atomic units (e.g., H=7 means two ferromagnetic layers are three atom-thick (FIG. 1d). The molecule is represented by one atom thick hollow rectangle placed between the metal electrodes (FIG. 1e). Molecules on edge are represented by atom-like units (FIGS. 1d and e). To better understand the connection of molecule analogs (e.g., atom like feature) with magnetic films one need to zoom in the interface between molecule and magnetic electrodes. FIG. 1e shows the interfacial atomic structure and critical parameters defining the properties of MTJMSD. The layer between the top and bottom FM electrodes represents the molecule layer with the hollow interior (FIG. 1e). Since experimentally molecules are only placed around the insulator perimeter (FIG. 1b), to match the description atomic-scale molecule analogs are present along the hollow rectangle perimeter (FIG. 1e). The empty space in the rectangle of the 3D MSD model represents the insulator used in experimental study (FIG. 1a).

In some embodiment of the present invention, the Monte Carlo Simulation for MSD (MCSMSD) program was capable of simulating a wide range of molecule-ferromagnet coupling by varying the magnitude of interaction parameters (JmL and JmR). Molecule coupling with two metal electrode is always in competition with coupling via the insulator. To make the Monte Carlo Simulation (MCS) study realistic, the strength of direct coupling between the two-metal electrode via hollow space was varied. The MCS program generally allowed the variation of the coupling parameter via an empty space, i.e., insulator. Competition between molecule-induced exchange coupling and insulator-induced coupling enables the study of many practical situations observed during the experimental fabrications. The evolved version of the MCS program has substantially enabled the variation in the properties of metal electrodes by way of varying inter-atomic exchange coupling parameters (JL and JR) and anisotropies independently. Based on solid-state physics J_{L} and J_{R} values set to zero, positive, and negative represent paramagnetic metal (e.g., Tantalum), ferromagnet (e.g., Nickel and cobalt), and antiferromagnet (e.g., FeMn alloys), respectively. The MCS program also enables the variation in anisotropy in the two FM electrodes. The program also covers fixed pillar shapes.

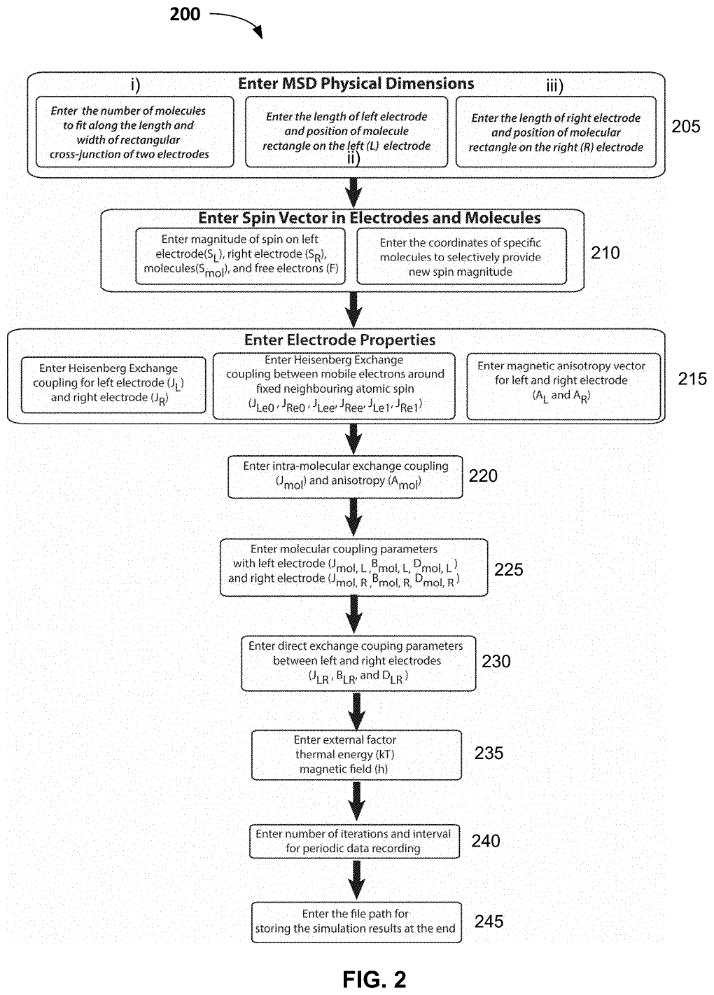

In another embodiment of the present invention, the MCS program may simulate cross junction shaped MTJMSDs, that were studied experimentally. Cross junction device geometry is also very helpful for the implementation of novel memory and logic algorithms. FIG. if shows an Atomic Force Microscope (AFM) image of the cross junction shaped MTJ with exposed side edges. The MCS program may simulate the cumulative effect of various defects present within the cross-junction area (FIG. 1g). FIG. 1h and FIG. 1i show a 3D illustration of experimentally studied exposed edge MTJ before and after molecular channel hosting. Cross junction-shaped MTJMSD brings tremendous opportunities to investigate a large variety of molecules as potential device elements and gateway to limitless opportunities. Two particular examples are shown by way of example, and not limitation, in FIG. 1j and FIG. 1k. The MCS program may represent cross junction-shaped MTJMSD with a 3D Heisenberg lattice model (FIG. 1l). Molecules along the edges are represented by an empty rectangle (FIG. 1l). The impact of the nature of the interaction of molecules with the two FM electrodes is investigated by varying the molecule-metal exchange coupling parameters (FIG. 1m). The MCS program of the present exemplary embodiment facilitates, if not enables, the investigation of a more significant, if not full, range of weak to strong molecule metal couplings via associated parameters in the master energy equation discussed ahead. The MCSMSD master energy equation involves strong Heisenberg exchange coupling (JmL and JmR), intermediate Biquadratic coupling (BmL and BmR), and weak dipolar coupling (DmL and DmR (FIG. 1m). The MCS program is also capable of varying the dimensions of metal electrodes and magnetic anisotropies in different directions (Ax, Ay, and Az) (FIG. 1m). The MCSMSD of one exemplary embodiment of the present invention may follow the steps shown by way of example, and not limitation, in the flow chart (FIG. 2) to define MSD properties via input parameters.

In some embodiment of the present invention, the disclosed MCS simulation program produces equilibrium properties of configurable molecular spintronics devices models comprising configurable magnetic molecules, configurable ferromagnetic electrodes, configurable nature of molecule-metal interactions, under configurable temperature and magnetic field. Configurability of different parts of MSD is achieved by the variation of user-defined parameters. The effect of different parameters is quantified by the master energy equation developed for MCS simulation of MSDs. The comprehensive master energy equation includes energy terms specific to molecules, electrodes, and weak to the strong interaction between molecules and electrodes. The MCS process, as exemplified in the present embodiment, is based on Markov random walk process to move MSD model from initial high energy arbitrary state to low energy stable state after billions of steps or iterations. During each iteration or step, a randomly new spin direction is created in 3D in a spherical coordinate system at a randomly selected location in MSD. A new spin state is accepted or rejected using Metropolis algorithm shown by way of example, and not limitation, in FIG. 2. The Metropolis algorithm is dependent on the master energy equation in making acceptance and rejection. Every change in parameter impacts the energy equation that translates into stabilizing a corresponding equilibrium state of a targeted MSD. The connection of each parameter with a specific energy term in the master energy equation for the MSD is the following:

$$E = - {J}_{L} ( {\sum }_{i ∈ L} \vec{{S}_{i}} \cdot {\vec{S}}_{i + 1} - {J}_{R} ( {\sum }_{i ∈ R} \vec{{S}_{i}} \cdot {\vec{S}}_{i + 1} ) - {J}_{Le 0} ( {\sum }_{i ∈ L} \vec{{S}_{i}} \cdot \vec{{F}_{i}} ) - {J}_{Le 1} ( {\sum }_{i ∈ L} \vec{{S}_{i}} \cdot {\vec{F}}_{i \pm 1} ) - {J}_{Re 0} ( {\sum }_{i ∈ R} \vec{{S}_{i}} \cdot \vec{{F}_{i}} ) - {J}_{Re 1} ( {\sum }_{i ∈ R} \vec{{S}_{i}} \cdot {\vec{F}}_{i \pm 1} ) - {J}_{Lee} ( {\sum }_{i ∈ L} \vec{{F}_{i}} \cdot {\vec{F}}_{i + 1} ) - {J}_{Ree} ( {\sum }_{i ∈ R} \vec{{F}_{i}} \cdot {\vec{F}}_{i + 1} ) - {A}_{Lx} ( {\sum }_{i ∈ L} {\vec{S}}_{ix}^{2} ) - {A}_{Ly} ( {\sum }_{i ∈ L} {\vec{S}}_{iy}^{2} ) - {A}_{Lz} ( {\sum }_{i ∈ L} {\vec{S}}_{iz}^{2} ) - {A}_{Rx} ( {\sum }_{i ∈ R} {\vec{S}}_{ix}^{2} ) - {A}_{Ry} ( {\sum }_{i ∈ R} {\vec{S}}_{iy}^{2} ) - {A}_{Rz} ( {\sum }_{i ∈ R} {\vec{S}}_{iz}^{2} ) - {J}_{LR} ( {\sum }_{i ∈ L , j ∈ R} \vec{{S}_{i}} \cdot \vec{{S}_{j}} ) - {B}_{LR} ( {\sum }_{i ∈ L , j ∈ R} {( \vec{{S}_{i}} \cdot \vec{{S}_{j}} )}^{2} + {\sum }_{i ∈ L , j ∈ R} {D}_{LR} \{ \frac{\vec{{S}_{i}} \cdot \vec{{S}_{j}}}{{r}_{i , j}^{3}} - 3 \frac{( \vec{{S}_{i}} {\cdot r}_{i , j}^{\to } ) ( {\vec{S}}_{i + 1 ( mol )} {\cdot r}_{i , j}^{\to } )}{{r}_{i , j}^{5}} \} - {J}_{mol} ( {\sum }_{i - 1 ∈ mol , i ∈ mol} {\vec{S}}_{i - 1 ( mol )} \cdot {\vec{S}}_{i ( mol )} ) - {A}_{mol} ( {\sum }_{i ∈ mol} {\vec{S}}_{i ( mol )}^{2} ) - {J}_{mol , L} ( {\sum }_{i ∈ L , i + 1 ∈ mol} \vec{{S}_{i}} \cdot {\vec{S}}_{i + 1 ( mol )} ) - {J}_{mol , R} ( {\sum }_{i - 1 ∈ mol , i ∈ R} {\vec{S}}_{i - 1 ( mol )} \cdot \vec{{S}_{i}} ) - {B}_{mol , L} ( {\sum }_{i ∈ L , i + 1 ∈ mol} {( \vec{{S}_{i}} \cdot {\vec{S}}_{i + 1 ( mol )} )}^{2} - {B}_{mol , R} ( {\sum }_{i - 1 ∈ mol , i ∈ R} {( {\vec{S}}_{i - 1 ( mol )} \cdot \vec{{S}_{i}} )}^{2} + {D}_{mol , L} ( {\sum }_{i ∈ L , i + 1 ∈ mol} \{ \frac{\vec{{S}_{i}} \cdot {\vec{S}}_{i + 1 ( mol )}}{{r}_{i , i + 1 ( mol )}^{3}} - 3 \frac{( \vec{{S}_{i}} {\cdot r}_{i , i + 1}^{\to } ) ( {\vec{S}}_{i + 1 ( mol )} {\cdot r}_{i , i + 1}^{\to } )}{{r}_{i , i + 1 ( mol )}^{5}} \} + {D}_{mol , R} ( {\sum }_{i ∈ R , i - 1 ∈ mol} \{ \frac{{\vec{S}}_{i - 1 ( mol )} \cdot \vec{{S}_{i}}}{{r}_{i - 1 ( mol ) , i}^{3}} - 3 \frac{( {\vec{S}}_{i - 1 ( mol )} {\cdot r}_{i - 1 , i}^{\to } ) ( \vec{{S}_{i}} {\cdot r}_{i - 1 , i}^{\to } )}{{r}_{i - 1 ( mol ) , i}^{5}} \} - {\sum }_{i ∈ L , R , Mol} h• \vec{{S}_{i}}$$

Description of Relation Between the Parameters in the Master Energy Equation and Associated MSD Property:

Configuring a Spin (e.g., Magnetic Moment) at Each Atomic Site of MSD:

The disclosed approach may allow configuring a magnitude of the spin vector (shown by S) of the two electrodes. The two electrodes that make the bond with molecules are referred to here as the left electrode (identified by L), and the right electrode (identified by the R). Spins of full molecule body are identified by “mol”. In some embodiment of the present invention, the Heisenberg model is utilized for Monte Carlo simulation to give all the spin vectors of metal and molecules (S^{⊥}→_i) align in any direction in 3D space. The disclosed MCSMSD method may allow user-defined arbitrary selection of any molecule location to define the magnitude of spin vector locally of a specific molecule. The provision of selecting the molecules arbitrarily enable the MCS program to achieve the following functionalities: (i) control the population of active molecules between electrodes, (ii) enable the study of situation where multiple types of molecules with different spin states are active, (iii) study the impact of different spin states on a molecule since actual molecules may switch among different spin states.

Configuring and Defining the Types of Electrodes Used in MSD:

To define types of the metal electrode to be simulated, the J_{L} and J_{R} parameters are changed. The J_{L} and J_{R} parameters represent the Heisenberg exchange coupling strengths present between the nearest neighbors of the FM electrodes. Other inter-atomic interactions beyond nearest neighbors were discarded. The positive sign of the J_{L} and J_{R} parameters represent ferromagnetic electrodes materials. The negative sign of the J_{L} and J_{R} parameters represent antiferromagnetic electrode materials. And zero value of the J_{L} and J_{R} parameters represent paramagnetic electrode materials. Sigma sign represents the sum of vector dot (•) products of nearest neighboring spins in electrodes used for MSD. Summation is performed along the two electrodes' length, width, and height dimensions. Hence, summation sign (Σ) covers the impact of the physical dimensions of the two metal electrodes in the MCS simulation.

Configuring and Defining the Effect of Spin Fluctuations and Impact of the Free Electron:

An electrode material may be metal, semiconductor, insulator, depending on the availability of free electron. In one embodiment of the present invention, the MCS simulation methodology defines additional spin vector (Fᵢ) at each atom site in two electrodes. Spin vector Fᵢ represents the presence of a movable electron residing around each atom in two electrodes. How easily an electron (Fᵢ) may free up from the fixed atom site is governed by the exchange coupling parameters J_{Le0} in the left electrode and J_{Re0} in the right ferromagnetic electrode. J_{Le0}=J_{Re0}=0 define completely independent electrons. On the other hand, J_{Le0}=J_{Re0}=1 or −1 represents a completely bound electron similar to the insulating material case. 0<J_{Le0} and J_{Re0}<1 represent various possibilities representing electrodes to be metallic, semiconducting, and insulating materials. Electron coupling with a nearest fixed neighboring atom on the left and right electrodes is defined by J_{Le1} and J_{Re1}, respectively. Varying J_{Le1} and J_{Re1} enable electron potential to hop to other sites and propagate in the electrode. The magnitude of the spin vector for the electrons around fixed sites may be configured independently. Adjusting the magnitude of free electron F represents the screening effect created by the surrounding lattice. The variation in the magnitude of fixed atom spin and associated electron spin may represent a wide range of materials used as electrodes in the disclosed MCS program for the MSD (MCSMSD) program.

Configuring and Defining the Anisotropy of Magnetic Electrodes:

Anisotropy is a critical factor in simulating MSD properties. In MCSMSD, anisotropy is configured by configuring the three components along the x,y, and z-axis. For the left electrode A_{Lx}, A_{Ly}, and A_{Lz} are provided. For the right electrode, anisotropy was varied A_{Rx}, A_{Ry}, and A_{Rz}. Adjusting the three components of anisotropy enable MCS simulation to include materials with (i) single direction anisotropy, (ii) in plane anisotropy, and (iii) out of plane anisotropy. The ability to configure anisotropy enables MCSMSD to investigate the properties of a molecule with a wide range of electrode materials with different magnetic hardness.

Configuring and Defining the Molecule's Internal Structure:

The molecule may have multiple components with the spin that are connected to each other to yield a net molecular spin. The property of a molecule is defined by two factors: (i) the strength of exchange coupling between different components of the molecule (Jmol) and (ii) the molecular anisotropy factor (Amol). The disclosed MCSMSD program allows varying the magnitude of spins of the complete molecules or individual components of the molecules. The spin of the molecule may be fixed due to the number of subsections defined in the molecular unit and by changing the magnitude of the spin vector.

Configuring and Defining the Insulating Spacer Property:

The MSD depends on the quality of the insulating spacer placed between two magnetic electrodes (FIG. 1a and FIG. 1h). The disclosed MCSMSD program may define the quality of the insulating barrier by configuring J_{LR}, B_{LR}, and D_{LR} factors. J_{LR} factor is the Heisenberg type exchange coupling parameter connecting the spins of two ferromagnetic electrodes via the insulating gap. Large J_{LR} means the insulating gap between two magnetic electrodes is very weak and has several defects. However, for encompassing intermediate-level coupling, B_{LR} is included. Large B_{LR} means the insulating barrier is very thin or has another category of defects that promote approximately 90-degree alignment between two magnetic electrodes. For the weakest case of coupling dipolar coupling (D_{LR}) parameter is included in the master energy equation. Hence, the design of a practical molecule device element-dominated MSD may require consideration of the nature of coupling present between two electrodes.

Configuring and Defining the Molecule-Magnetic Electrode Interaction:

The MSD requires that magnetic molecules simultaneously interact with the two magnetic electrodes, referred to as left and right electrodes in the Heisenberg model (FIG. 1l). In the MCSMSD program, the magnetic interaction between the magnetic molecule and magnetic electrode may be configured via three well mechanisms (i) Heisenberg type exchange coupling applicable to nearest neighbors, (ii) intermediate strength biquadratic exchange coupling, and (iii) long-range dipolar coupling. In some embodiment, the MCSMSD program includes energy terms for all three interaction types. The Heisenberg exchange coupling between molecule and left electrode, and molecule and the right electrode is governed by the sign and magnitude of J_{mL}, and J_{mR} (user-defined) parameters. The combined role of the J_{mL} and J_{mR} parameters is to make two magnetic electrodes parallel or antiparallel with respect to molecule spin vector. Similarly, biquadratic coupling B_{mL} and B_{mR} roles are to make molecule spin aligned at about 90° with respect to the ferromagnetic electrode. Disclosed MCSMSD program mainly focuses on Heisenberg type exchange interaction to represent the strong molecule-induced coupling. Biquadratic coupling represents an intermediate level of coupling between molecule and ferromagnets. This simulation strategy also may include very weakly connected molecules to the metal electrodes via long-range dipolar exchange coupling. Dipolar weak molecular exchange coupling is varied by configuring D_{mL} and D_{mR} parameters independently.

Configuring the External Magnetic Field:

The external magnetic field is controlled by the parameter h in the master energy equation. Application of magnetic field is very helpful in understanding the MSD response in different scenarios involving various combinations of MSD components deemed important for producing practical devices.

Configuring the Number of Iterations:

The number of iterations as input may allow the MCSMSD to make the desired number of attempts to transition from the initial random state to a stable equilibrium state. The number of input iterations is equivalent to the time parameter in experimental studies. Actual experimental studies showed that the MSD requires some time after connecting magnetic molecules to magnetic electrodes to reach the stable states (FIG. 1B).

The present invention will now be described in detail with reference to embodiments thereof as illustrated in the accompanying drawings.

FIG. 1 is an illustration of an exemplary Molecular Spintronics Device (MSD) on which a simulation program is applied, in accordance with an embodiment of the present invention. Various stages of the simulation process 100 are shown. In one embodiment of the present invention, a trilayer ferromagnet-insulator-ferromagnet such as, but not limited to, Nickel-insulator-Cobalt (a) is transformed in MSD (b) by bonding magnetic molecules (c) across the insulator. MSD can also include many forms such as Iron-insulator-Nickel, Nickel-insulator-Nickel. In a Monte Carlo Simulation (MCS), experimental MSD is represented by ball and stick model (d). Orange ball represent complex molecules, such as shown by way of example, and not limitation, in panel (c). The properties of ferromagnets are controlled by controlling parameters used in basic material equations (e.g., J_{L} and J_{R}). In MCS, the properties of interactions between the top and bottom ferromagnet layer via the molecules is controlled by controlling parameters used in the master energy equations (e.g., J_{mL} and J_{mR}) (e). The MCS program may study complex MSDs like cross junction shaped MSDs (f) and also consider practical limitations such as the presence of defects in the MSDs (g) by representing defects with a parameter (e.g., Jᵢ) in the energy algorithm (h). The MCS program represent experimentally studied MSD designs and different molecules (i) connected to ferromagnetic electrodes (j) and (k). The Monte Carlo Simulation for MSD (MCSMSD) represent magnetic tunnel junction-based MSDs (MTJMSD) (l) by a 3D ball and stick model (m). Each ball represents an atom or molecule and each stick represent the nature of bonding. The MCS program covers the vast range of metals, molecules, and the bonding between molecules and metals. Examples of molecules include molecules with a net magnetic spin such as, but not limited to, porphyrin, single molecule magnet, organometallic clusters, etc.

FIG. 2 is an illustration of an exemplary input flow chart 200 for configuring a 3D model of a molecular spintronics device (MSD) to be simulated by the MCSMSD program, in accordance with an embodiment of the present invention. In one embodiment of the present invention, the MCSMSD program starts with the input and/or entry of parameters to configure a desired MSD 3D model. An input file is produced by entry of the physical dimensions of the MSD where, in a Step 205, the MCSMSD program asks i) entry of the number of molecules to fit along the length and width of the cross junction between two electrodes; ii) entering the length and width of the magnetic electrode and coordinates of points where molecules appear, and iii) entering the thickness of magnetic electrodes and the number of atoms in the molecules. In a Step 210, a spin vector in electrodes and molecules is entered. First, enter the default magnitude of the spin on the left electrode (S_{L}), right electrode (S_{R}), molecules (Smol), and free electrons (F). If specific molecules are to be given different spin vector magnitude, then enter the coordinates of specific molecules and their new spin magnitude. In a Step 215, the electrode properties are entered. First, enter Heisenberg exchange coupling parameters (J_{L} and J_{R}) to configure magnetic electrodes as ferromagnetic, paramagnetic, and antiferromagnetic. The magnitude of J_{L} and J_{R} control the Curie or Neel temperature like fundamental attributes of magnetic electrodes. Second, to simulate the properties of mobile electrons in the magnetic electrodes, enter the magnitude and sign of electron-related exchange parameters with the host site and nearest neighbor site. Also, provide the Jₑₑ parameter that represents correlated electron cloud in two magnetic electrodes. And third, enter the magnetic anisotropy along the x, y, z directions. In a Step 220, enter the molecules internal properties. In many, if not most, practical situations, for simple molecules where the molecule is represented by the single atomic analog, the value of Jmol and Amol may be set at, or near, zero. If multiple atoms represent molecules, the exchange coupling between the two atoms in a molecule is configured by Jmol. The anisotropy of the whole molecule is configured by Amol. In a Step 225, enter the molecule-magnetic electrode interaction parameters. Each molecule is simultaneously connected to two magnetic electrodes. In some embodiment of the present invention, the MCSMSD allows configuring the properties of molecule interaction with the left and right electrodes independently to cover a vast range of cases. The MCSMSD allows a strong Heisenberg exchange coupling (J_{mol,L} and J_{mol,R}), biquadratic exchange coupling (B_{mol,L} and B_{mol,R}), and long-range dipolar coupling (D_{mol,L} and D_{mol,R}). The three types of couplings cover wide spectrum of interaction possibilities between two magnetic entities. In a Step 230, enter the direct exchange coupling parameters between the left and right electrodes. Two magnetic electrodes may also directly interact via the insulating space, shown by the empty space in the MCSMSD model (FIG. 1e). The nature of direct interaction is configured by the J_{LR} (Heisenberg exchange coupling), B_{LR} (Biquadratic exchange coupling), and D_{LR} (Dipolar exchange coupling) parameters. In a Step 235, enter the External Factor. The MCSMSD may explore MSD properties at different thermal energy and magnetic field. The kT parameter may control the thermal energy of the MSD and the magnetic field is controlled by the magnetic field (h). In a Step 240, enter the number of iterations. The MCSMSD may attain an equilibrium state when each atom and molecule have opportunities to evaluate a wide range of random spin states and settle with one that produces the least amount of energy according to master energy equation. To accomplish this task, the MCSMSD allow configuring the number of iterations. In a Step 245, the MCSMSD enables the recording of intermediate data periodically. The interval for recording may be provided as user-defined input.

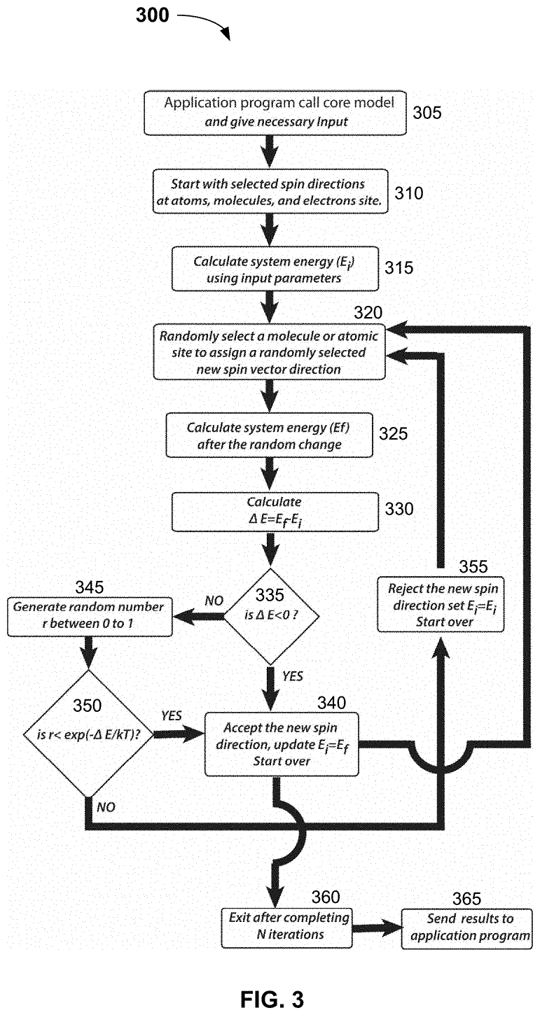

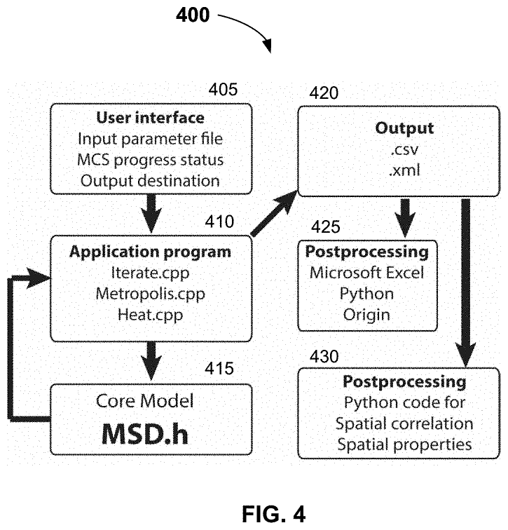

FIG. 3 is an illustration of an exemplary flow chart 300 showing acceptance and rejection process of a newly created state based on a Metropolis algorithm, in accordance with an embodiment of the present invention. In one embodiment of the present invention, in a Step 305, the exemplary MCSMSD of the present embodiment application program use the core model (MSD.h) (see FIG. 4) to evolve a desired MSD from an initial state to an equilibrium state. The exemplary MCSMSD of the present embodiment utilizes input data to attain a stable state MSD as per the Markov chain process (random walk) and Metropolis algorithm. Each Metropolis algorithm-driven iteration constitutes the step of randomly selecting a location in MSD and changing the spin vector direction at this location, followed by conducting a test to accept or reject the new spin state. The steps in a single iteration are followed in a Step 310, perform an initialization of spin directions. The first step is to initialize the spin of molecules and magnetic electrodes in random directions. The exemplary MCSMSD of the present embodiment also may initialize all the spins in a single direction. In a Step 315, perform an initial energy calculation (E). The master energy equation calculates an initial energy using the input parameters and spin vector directions. In a Step 320, assigning a randomly created new spin direction at a randomly selected location. In this step, a random number generator is utilized to create a site location in the MSD. A second random number generator may produce a new random spin direction in the spherical coordinate system for the randomly selected location. In a Step 325, calculating the new energy after the change in the spin direction at a random site in MSD. Using the master energy equation of the updated system was calculated (E_{f}). In a Step 330, compute the difference E_{f} and Eᵢ. The difference is termed as ΔE and used for logic operation for accepting and rejecting the new spin state. In a Step 335, a determination is made if ΔE<0, then it means a new state reduced MSD energy, and this change is accepted in a Step 340. If ΔE>0, a new state is rejected based on the Metropolis algorithm criteria.

For the Metropolis algorithm criteria, a random number r is created between 0 and 1. And exp(−ΔE/kT) is computed in a Step 350. In a Step 350, a magnitude of exp(−ΔE/kT) is compared with the random number between 0 and 1. If r<exp(−ΔE/kT), the probability of stabilizing the new state is more than a random probability, and the new state is accepted in a Step 340. After the acceptance step spin state of the randomly selected site is updated with the new state, and initial energy is updated. The next step is to start over and repeat Step 320 of selecting a site randomly and updating with a randomly selected spin direction and conduct the acceptance in Step 340 and rejection step in a Step 355. After the rejection step in Step 355, the original spin state at the randomly selected site is restored. After the rejection step, the next step was to start over again. A new site is selected randomly, and a random new spin state is created. The process (iterations) is repeated ˜million to billions of times to ensure each site get enough opportunity to reach equilibrium state. In a Step 360, after a desired number of iterations are completed, the application exits. In a Step 365, the results are passed on to a calling application program.

FIG. 4 is an illustration of an exemplary MCSMSD application program functional layout 400, in accordance with an embodiment of the present invention. The functional layout shown may be considered to be a general software modules logical function architecture for at least some practical embodiments. In one embodiment of the present invention, the exemplary MCSMSD functional layout 400 may include, but not limited to, a User interface 405, Application program 410, Core model 415, Output 420, and Postprocessing 425 430. User interface 405 accepts an input parameter file, provide MCS progress update, and configure the result output definition. User interface 405 is connected to application program 410. Application program 410 may run based on core model 415 that produce results that are organized by user interface 405 in the desired output form 420. Output file 420 may be created in .csv and .xml format. The results are subsequently postprocess 425 and 430 to gain more insights. Raw data may be postprocessed 425 and 430 using conventional software or newly created programs to investigate new insights. An input file via user-interface 405 is channeled to the desired application program 410 including but not limited to MCSMSD. The MCSMSD may comprise, but not limited to, Iterate.cpp, Metropolis.cpp, and Heat.cpp application programs. Each application program has very different function. The Iterate.cpp application program may be utilized to determine the number of iterations needed to reach an equilibrium state. The Metropolis.cpp application program may allow the exemplary MCSMSD of the present embodiment to vary simulation multiple parameters over a range and only record equilibrium state properties. Similarly, the Heat.cpp application programs is designed to vary the external thermal energy. In essence, all three application programs implement new state creation followed by acceptance 340 or rejection 355 algorithm in FIG. 3. The common function is placed in the core model MSD.h program 415. The MSD.h Core model program 415 is invoked by all the application program during each iteration.

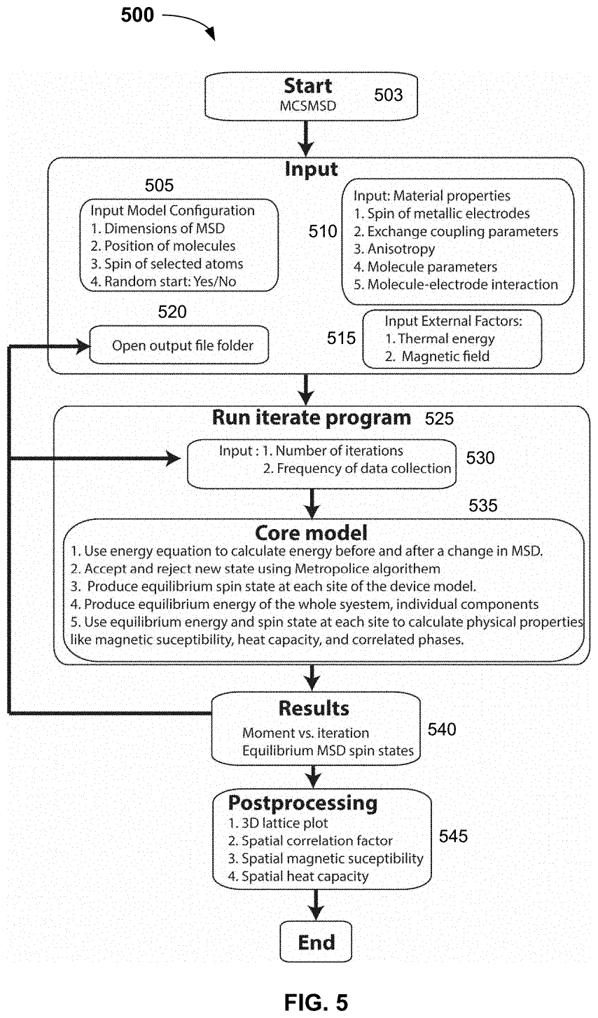

FIG. 5 is an illustration of an exemplary flow chart 500 showing a general structure of an exemplary MCSMSD program from start to end, in accordance with an embodiment of the present invention. In one embodiment of the present invention, FIG. 5 shows the start to end of a simulation study mainly utilizing the Iterate.cpp program. Flow chart 500 shows the plan of a full MCS study on MSD. In a Step 503, a start of the present MCSMSD program embodiment begins with an input.txt file that may allow under-defined MSD attributes. In a Step 505, the input file MSD shape and size is configured. In a Step 510, the input file may allow defining the material properties/parameters. In a Step 515, the input file may allow defining the external factors such as, but not limited to, thermal energy/heat and magnetic field. In a Step 520, the input file opens a folder to write results (output file). Next, the iterate program is run in a Step 525. In a Step 530, the iterate program may take input from the input.txt file. In addition, the iterate program may prompt a user to enter or mention the number of iterations and iteration interval after which data is to be stored periodically. Next, in a Step 535, the iterate program may call the core model to perform the Metropolis algorithm as per the strategy defined in the flow chart shown by way of example, and not limitation, in FIG. 3. After the completion of all the iteration, in a Step 540, moment vs iteration may be plotted to evaluate a critical number of iterations required to reach an equilibrium state. The information about the critical number of iterations is fed into further simulations to produce an MSD in equilibrium state. The iterate application program may produce one file per full simulation. In a Step 545, results of the different simulations may be analyzed (postprocessing) including, but not limited to, 3D lattice plot, spatial correlation factor, spatial magnetic susceptibility, and spatial heat capacity. Finally, the iterate program ends.

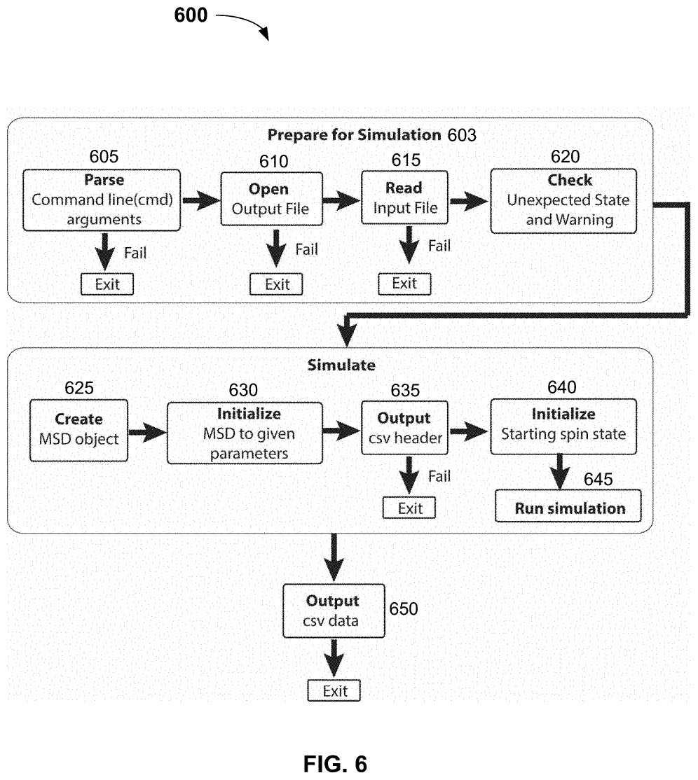

FIG. 6 is an illustration of an exemplary flow chart 600 showing a general structure of an Iterate.cpp application that is used for studying evolution of a desired MSD from a random state to equilibrium state for fixed value set of parameters, in accordance with an embodiment of the present invention. In an embodiment of the present invention, Iterate.cpp application may include a process flow 600 that occurs specifically in the MCSMSD's Iterate.cpp application program. For example, without limitation, in a Step 603, the Iterate.cpp application first prepare for simulation. In a Step 605, preparation may include Parsing the input from command lines to understand instructions. Only limited input is provided via the command line. The Iterate.cpp application prompt for number of iterations and interval for storing data periodically via the command line. The application exits if the instruction is not correct and provide an error message. In a Step 610, open the output file in the user defined destination application folder. Exit if output file and destination information is wrong. In a Step 615, read input from the separate input file that contains major portion of a user-defined input. The input file provides desired information of MSD size, shape, molecules, magnetic electrodes, and external factors. In a Step 620, do a check for an unexpected state and give a warning. Next step is about running the simulation. In a Step 625, the Iterate.cpp application may create input file to be fed in the core model (e.g., MSD.h). Based on the iterate.cpp input, the MSD.h core program is initialized in a Step 630. In a Step 635, an output stream is created to a designated folder. In a Step 640, an initial spin state is created throughout the Molecular Spintronics Device (MSD) model to begin. And, in a Step 645, the simulation begin. The Iterate.cpp program calls the MSD.h core program for each iteration to progress to the next iteration. Once all the predefined iterations are completed, in a Step 650, results are sent in a csv file format to the Output. The Iterate.cpp application program may run again when a parameter value is changed and may produce one .csv file per run. After which, the Iterate.cpp application program ends and exits.

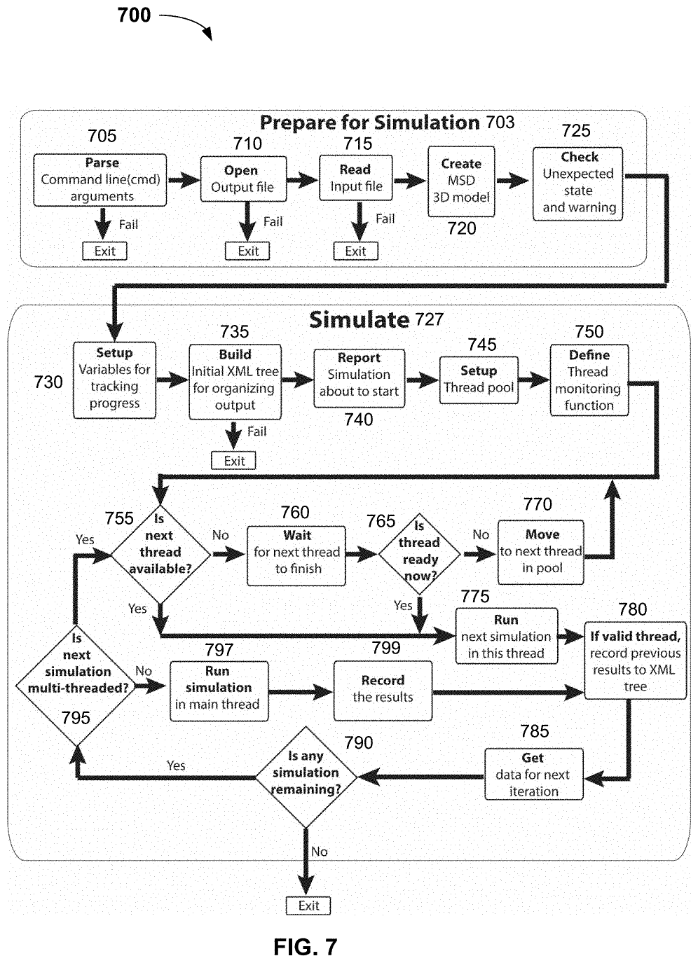

FIG. 7 is an illustration of an exemplary flow chart 700 showing a general structure of a Metropolis.cpp application that is used for studying a desired MSD for range of simulation parameters and storing all data in an XML tree, in accordance with an embodiment of the present invention.

In some embodiments, the MCSMSD may also be designed to simulate MSD properties efficiently for the range of one or more input parameters. The exemplary MCSMSD of the present embodiment is designed to run a simulation efficiently for MSDs involving several thousand of atoms and molecules with a regular desktop computer. For the study where a simulation parameter varies over a range, the Metropolis.cpp application program is employed. For example, without limitation, if two molecule parameters to magnetic electrode coupling energy (J_{mL}) varying from approximately −1 to 1 in the step of about 0.1, and thermal energy (kT) varying from approximately 0 to 1 in the step of about 0.1, then a number of individual simulations may be around 200 (i.e., 20×10=200). To run at least 200 simulations and organizing the results, the MCSMSD's Metropolis.cpp application program may be engaged. However, the Metropolis.cpp application program may only work with fix MSD shape and size and may not change physical dimension related parameters.

Similar to the Iterate.cpp application program of FIG. 6, the Metropolis.cpp application program also works in two broad sections. “Prepare for Simulation” 703 and “Simulate” 727 sections. In one embodiment of the present invention, the Metropolis.cpp application program prepares for simulation 703 as follows: In a Step 705, Parse command line argument to pick simulation related instructions and ‘Exit’ if a problem with the command line is observed. Next, in a Step 710, Open the output file folder, exit if the path is not recognized. Then, in a Step 715, read the separate Input file which may contain major portion of the input. In a Step 720, the input file has specific information about the range of values needed to be studied for an intended or predetermined list of parameters. In a Step 725, Check for unexpected state and warning. The “Simulate” section 727 begin with setup of variable for tracking progress in a Step 730. Next, in a Step 735, is the Build step initializing the XML tree for organizing output. The format is capable of storing results of individual simulations specific to a set of input parameters along with the parameter information. Any issue preventing Building of XML tree may cause failure and program exit. After the successful Build step, in a Step 740, Metropolis.cpp performs Report step to inform that the simulation is about to start. Next, in a Step 745, Metropolis.cpp application program conducts a Setup step to setup a thread pool to efficiently run the multiple simulations in parallel in Desktop computers. Setup step 745 is followed by a Define Step 750. Define step 750 performs thread monitoring function in the computer. An input from the thread monitoring function keeps track of number of available threads. In a Step 755, a logic operation is conducted to determine if a particular thread is busy or not. For example, without limitation, “Is next thread available?” verify if a particular thread considered for running a simulation is busy. If thread is busy, then, in a Step 760, Wait step occurs and in a Step 765, conducts an availability status check by performing “Is thread ready now?”. If a thread is still busy, in a Step 770, thread monitoring function performs a Move step to seek next available thread and conduct simulation. If answer to “Is thread ready now?” is yes, then, in a Step 775, Run next simulation in this thread. If “Is next thread available?” logic step result is Yes, then, in a Step 775, the thread may be employed for running the next simulation. If a valid thread is used for running a next simulation, then, in a Step 780, record previous results to an XML tree. After appending the results thread monitoring function, in a Step 785, perform Get step to fetch the data for next iteration followed by a status check logic operation “Is any simulation remaining?” in a Step 790. If no simulation remaining, the active simulation is completed, and program terminate. If there are simulation(s) remaining, then, in a Step 795, a logic operation is performed to check if next simulation mult-threaded? If yes, the simulation checks the availability of thread in Step 755. If the simulation is a single thread, then, in a Step 797, Run the simulation in a main thread and in a Step 799, perform Record step to record the results in the XML tree.

It may be noted that each Run simulation step in flow chart 700 is substantially equivalent to running the Iterate.cpp application program. In the Metropolis.cpp application program, the focus is directed on MSD properties recorded in the equilibrium states. To record equilibrium or stable state MSD data, data generated during a transient stage may be discarded.

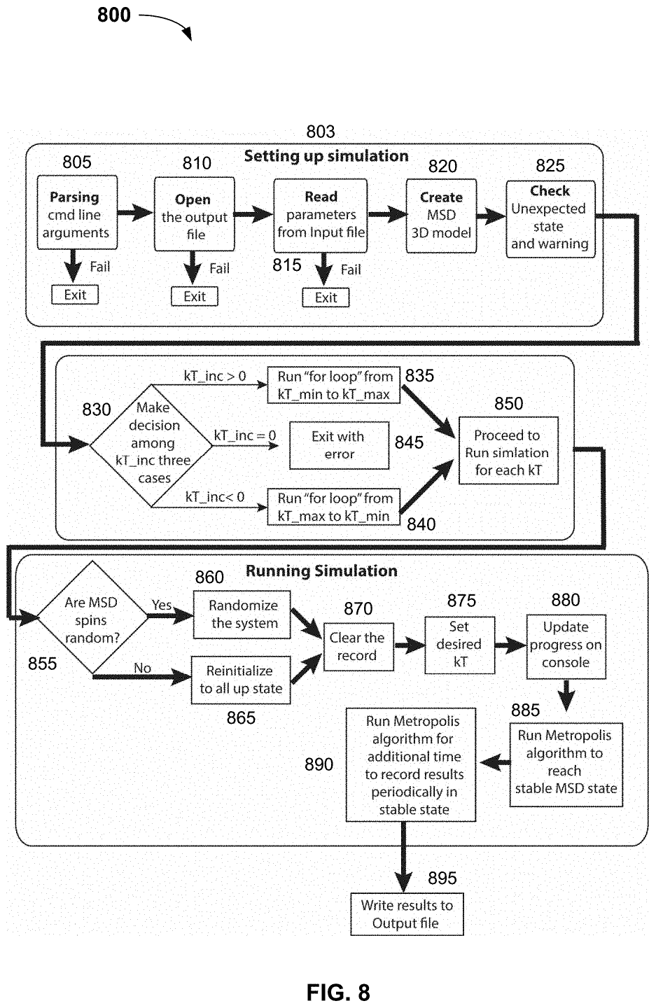

FIG. 8 is an illustration of an exemplary flow chart 800 showing a general structure of a Heat.cpp application program in MCSMSD group of programs, in accordance with an embodiment of the present invention. The Heat.cpp application program studies the effect of range of thermal energy (kT) variation. Referring to FIG. 4 and FIG. 8, as shown by way of example, and not limitation, in Step 410, MCSMSD also have Heat.cpp application program in addition to Iterate.cpp and Metropolis.cpp application programs. The Heat.cpp application program may allow variation of thermal energy kT over a range. MSD simulation data is only recorded in the equilibrium state. Also, thermal energy variation (kT variation) represents two very relevant cases when MSD may be heated or cooled down. Experimentally, the MSD may behave differently during heating and cooling. To understand the experimental studied, Heat.cpp application program is employed.

In one embodiment, the Heat.cpp application program begins with setting up a simulation in a Step 803. The simulation setup begins, in a Step 805, with parsing the command line arguments. In case of any abnormal entry, the program fails and exit. Next, in a Step 810, Heat.cpp opens an output file to save data in a .csv file format. If the output file is unrecognized, the program fails and exit. Next, in a Step 815, is Read parameters from the input file. Similar to Metropolis.cpp, the Heat.cpp program also provide the range of kT parameter(s). For example, without limitation, if kT is changing from about 0 to 1 in the step of approximately 0.2 then the number of simulations is more or less 5. Next, in a Step 820, creating a 3D model to feed into the Core model (MSD.h) and in a Step 825, Check for unexpected state and warning. Next, in a Step 830, Heat.cpp makes a decision by evaluating kT_Inc step. If kT_Inc>0, then, in a Step 835, run “for loop” from kT_min (lower end of the kT) and kT_max (higher end of the thermal energy). In a Step 850, Proceed to Run simulation for each kT. If kT_Inc<0, then, in a Step 865, run “for loop” from kT_max (higher end of the thermal energy) to kT_min (lower end of the kT). In Step 850, Proceed to Run simulation for each kT. And, if kT_Inc=0, then, in a Step 845, the program exits with an error.

Running the simulation section may begin, in a Step 855, with a logic operation to decide if the initial state of MSD is random? If yes, then in a Step 860, randomize the system. If no, in a Step 865, reinitialize to all up-spin state. Then in a Step 870, Clear the record in the destination file, followed by, in a Step 875, setting a desired kT and, in a Step 880, update progress on a console. In a Step 885, Run Metropolis algorithm to reach equilibrium state of the MSD. After crossing the threshold of number of iterations necessary to reach the equilibrium state, in a Step 890, the Heat.cpp application program may run a Metropolis algorithm for additional time to record results at desired interval in the MSD stable state. After completing the full range of kTs, in a Step 895, the Heat.cpp application program may write results in an Output file.

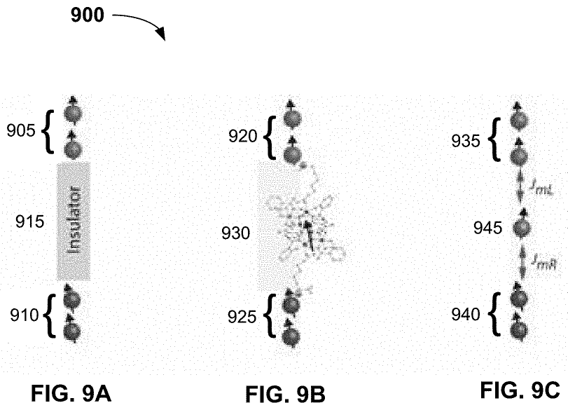

FIG. 9A is an atomic level illustration of an exemplary magnetic tunnel junction (MTJ) 900, in accordance with an embodiment of the present invention. The magnetic tunnel junction (MTJ) may include a first metal film atoms 905 such as iron, a second metal film atom 910 such as nickel, and an insulator separating the first and second metal film atoms with spin. The spin is shown by arrows. MTJ structure may ensure that two metal electrodes are always physically separated by an insulator. Hence, MTJ provides a molecule to serve as device element in the presence robust insulating spacer.

FIG. 9B is an illustration of an exemplary magnetic molecule connected to metal atoms with spin 901, in accordance with an embodiment of the present invention. MCSMSD simulates MSD where complex molecules of interest are present along with insulating spacer. FIG. 9B signifies the need of approximating complex molecules forming bonds with metal electrodes 920 and 925. MCSMSD is capable of simulating very basic few atoms systems to complex 3D pillar and cross junction shaped MTJMSDs.

FIG. 9C is an illustration of an exemplary result 902 of an MCS program strategy, in accordance with an embodiment of the present invention. In an embodiment of the present invention, actual molecules are replaced with atom like features. Molecule spin is replaced with the spin of the replacing atom. The insulator is replaced with an empty space. The molecule to metal contact is replaced by variables J_{mR} and J_{mL}. FIG. 9C signifies an MCSMSD approach to represent complex molecules with simple structure. The nature of weak to strong molecule-metal interaction is represented by the variables J_{mR} and J_{mL}. MCSMSD can also tackle other forms of nanoscale devices where nanostructure can be represented by the single atomic scale feature.

FIG. 10 is a block diagram depicting an exemplary client/server system which may be used by an exemplary web-enabled/networked embodiment of the present invention.

A communication system 1000 includes a multiplicity of clients with a sampling of clients denoted as a client 1002 and a client 1004, a multiplicity of local networks with a sampling of networks denoted as a local network 1006 and a local network 1008, a global network 1010 and a multiplicity of servers with a sampling of servers denoted as a server 1012 and a server 1014.

Client 1002 may communicate bi-directionally with local network 1006 via a communication channel 1016. Client 1004 may communicate bi-directionally with local network 1008 via a communication channel 1018. Local network 1006 may communicate bi-directionally with global network 1010 via a communication channel 1020. Local network 1008 may communicate bi-directionally with global network 1010 via a communication channel 1022. Global network 1010 may communicate bi-directionally with server 1012 and server 1014 via a communication channel 1024. Server 1012 and server 1014 may communicate bi-directionally with each other via communication channel 1024. Furthermore, clients 1002, 1004, local networks 1006, 1008, global network 1010 and servers 1012, 1014 may each communicate bi-directionally with each other.

In one embodiment, global network 1010 may operate as the Internet. It may be understood by those skilled in the art that communication system 1000 may take many different forms. Non-limiting examples of forms for communication system 1000 include local area networks (LANs), wide area networks (WANs), wired telephone networks, wireless networks, or any other network supporting data communication between respective entities.

Clients 1002 and 1004 may take many different forms. Non-limiting examples of clients 1002 and 1004 include personal computers, personal digital assistants (PDAs), cellular phones and smartphones.

Client 1002 includes a CPU 1026, a pointing device 1028, a keyboard 1030, a microphone 1032, a printer 1034, a memory 1036, a mass memory storage 1038, a GUI 1040, a video camera 1042, an input/output interface 1044 and a network interface 1046.

CPU 1026, pointing device 1028, keyboard 1030, microphone 1032, printer 1034, memory 1036, mass memory storage 1038, GUI 1040, video camera 1042, input/output interface 1044 and network interface 1046 may communicate in a unidirectional manner or a bi-directional manner with each other via a communication channel 1048. Communication channel 1048 may be configured as a single communication channel or a multiplicity of communication channels.

CPU 1026 may be comprised of a single processor or multiple processors. CPU 1026 may be of various types including micro-controllers (e.g., with embedded RAM/ROM) and microprocessors such as programmable devices (e.g., RISC or SISC based, or CPLDs and FPGAs) and devices not capable of being programmed such as gate array ASICs (Application Specific Integrated Circuits) or general-purpose microprocessors.

As is well known in the art, memory 1036 is used typically to transfer data and instructions to CPU 1026 in a bi-directional manner. Memory 1036, as discussed previously, may include any suitable computer-readable media, intended for data storage, such as those described above excluding any wired or wireless transmissions unless specifically noted. Mass memory storage 1038 may also be coupled bi-directionally to CPU 1026 and provides additional data storage capacity and may include any of the computer-readable media described above. Mass memory storage 1038 may be used to store programs, data and the like and is typically a secondary storage medium such as a hard disk. It may be appreciated that the information retained within mass memory storage 1038, may, in appropriate cases, be incorporated in standard fashion as part of memory 1036 as virtual memory.

CPU 1026 may be coupled to GUI 1040. GUI 1040 enables a user to view the operation of computer operating system and software. CPU 1026 may be coupled to pointing device 1028. Non-limiting examples of pointing device 1028 include computer mouse, trackball and touchpad. Pointing device 1028 enables a user with the capability to maneuver a computer cursor about the viewing area of GUI 1040 and select areas or features in the viewing area of GUI 1040. CPU 1026 may be coupled to keyboard 1030. Keyboard 1030 enables a user with the capability to input alphanumeric textual information to CPU 1026. CPU 1026 may be coupled to microphone 1032. Microphone 1032 enables audio produced by a user to be recorded, processed, and communicated by CPU 1026. CPU 1026 may be connected to printer 1034. Printer 1034 enables a user with the capability to print information to a sheet of paper. CPU 1026 may be connected to video camera 1042. Video camera 1042 enables video produced or captured by user to be recorded, processed, and communicated by CPU 1026.

CPU 1026 may also be coupled to input/output interface 1044 that connects to one or more input/output devices such as such as CD-ROM, video monitors, track balls, mice, keyboards, microphones, touch-sensitive displays, transducer card readers, magnetic or paper tape readers, tablets, styluses, voice or handwriting recognizers, or other well-known input devices such as, of course, other computers.

Finally, CPU 1026 optionally may be coupled to network interface 1046 which enables communication with an external device such as a database or a computer or telecommunications or internet network using an external connection shown generally as communication channel 1016, which may be implemented as a hardwired or wireless communications link using suitable conventional technologies. With such a connection, CPU 1026 might receive information from the network, or might output information to a network in the course of performing the method steps described in the teachings of the present invention.

Those skilled in the art may readily recognize, in light of and in accordance with the teachings of the present invention, that any of the foregoing steps and/or system modules may be suitably replaced, reordered, removed and additional steps and/or system modules may be inserted depending upon the needs of the particular application, and that the systems of the foregoing embodiments may be implemented using any of a wide variety of suitable processes and system modules, and is not limited to any particular computer hardware, software, middleware, firmware, microcode and the like. For any method steps described in the present application that may be carried out on a computing machine, a typical computer system may, when appropriately configured or designed, serve as a computer system in which those aspects of the invention may be embodied. Such computers referenced and/or described in this disclosure may be any kind of computer, either general purpose, or some specific purpose computer such as, but not limited to, a workstation, a mainframe, GPU, ASIC, etc. The programs may be written in C, or Java, Brew, or any other suitable programming language. The programs may be resident on a storage medium, e.g., magnetic, or optical, e.g., without limitation, the computer hard drive, a removable disk or media such as, without limitation, a memory stick or SD media, or other removable medium. The programs may also be run over a network, for example, without limitation, with a server or other machine sending signals to the local machine, which allows the local machine to carry out the operations described herein.

Those skilled in the art may readily recognize, in light of and in accordance with the teachings of the present invention, that any of the foregoing steps may be suitably replaced, reordered, removed and additional steps may be inserted depending upon the needs of the particular application. Moreover, the prescribed method steps of the foregoing embodiments may be implemented using any physical and/or hardware system that those skilled in the art may readily know is suitable in light of the foregoing teachings. For any method steps described in the present application that may be carried out on a computing machine, a typical computer system may, when appropriately configured or designed, serve as a computer system in which those aspects of the invention may be embodied. Thus, the present invention is not limited to any particular tangible means of implementation.

It may be further apparent to those skilled in the art that at least a portion of the novel method steps and/or system components of the present invention may be practiced and/or located in location(s) possibly outside the jurisdiction of the United States of America (USA), whereby it may be accordingly readily recognized that at least a subset of the novel method steps and/or system components in the foregoing embodiments must be practiced within the jurisdiction of the USA for the benefit of an entity therein or to achieve an object of the present invention. Thus, some alternate embodiments of the present invention may be configured to comprise a smaller subset of the foregoing means for and/or steps described that the applications designer may selectively decide, depending upon the practical considerations of the particular implementation, to carry out and/or locate within the jurisdiction of the USA. For example, without limitation, any of the foregoing described method steps and/or system components which may be performed remotely over a network (e.g., without limitation, a remotely located server) may be performed and/or located outside of the jurisdiction of the USA while the remaining method steps and/or system components (e.g., without limitation, a locally located client) of the forgoing embodiments are typically required to be located/performed in the USA for practical considerations. In client-server architectures, a remotely located server typically generates and transmits required information to a US based client, for use according to the teachings of the present invention. Depending upon the needs of the particular application, it may be readily apparent to those skilled in the art, in light of the teachings of the present invention, which aspects of the present invention may or should be located locally and which may or should be located remotely. Thus, for any claim's construction of the following claim limitations that are construed under 35 USC § 112 (6)/(f) it is intended that the corresponding means for and/or steps for carrying out the claimed function are the ones that are locally implemented within the jurisdiction of the USA, while the remaining aspect(s) performed or located remotely outside the USA are not intended to be construed under 35 USC § 112 (6) pre-AIA or 35 USC § 112 (f) post AIA.

It is noted that according to USA law, all claims must be set forth as a coherent, cooperating set of limitations that work in functional combination to achieve a useful result as a whole. Accordingly, for any claim having functional limitations interpreted under 35 USC § 112 (6)/(f) where the embodiment in question is implemented as a client-server system with a remote server located outside of the USA, each such recited function is intended to mean the function of combining, in a logical manner, the information of that claim limitation with at least one other limitation of the claim. For example, without limitation, in client-server systems where certain information claimed under 35 USC § 112 (6)/(f) is/(are) dependent on one or more remote servers located outside the USA, it is intended that each such recited function under 35 USC § 112 (6)/(f) is to be interpreted as the function of the local system receiving the remotely generated information required by a locally implemented claim limitation, wherein the structures and or steps which enable, and breath life into the expression of such functions claimed under 35 USC § 112 (6)/(f) are the corresponding steps and/or means located within the jurisdiction of the USA that receive and deliver that information to the client (e.g., without limitation, client-side processing and transmission networks in the USA). When this application is prosecuted or patented under a jurisdiction other than the USA, then “USA” in the foregoing should be replaced with the pertinent country or countries or legal organization(s) having enforceable patent infringement jurisdiction over the present patent application, and “35 USC § 112 (6)/(f)” should be replaced with the closest corresponding statute in the patent laws of such pertinent country or countries or legal organization(s).

All the features disclosed in this specification, including any accompanying abstract and drawings, may be replaced by alternative features serving the same, equivalent or similar purpose, unless expressly stated otherwise. Thus, unless expressly stated otherwise, each feature disclosed is one example only of a generic series of equivalent or similar features.

It is noted that according to USA law 35 USC § 112 (1), all claims must be supported by sufficient disclosure in the present patent specification, and any material known to those skilled in the art need not be explicitly disclosed. However, 35 USC § 112 (6) requires that structures corresponding to functional limitations interpreted under 35 USC § 112 (6) must be explicitly disclosed in the patent specification. Moreover, the USPTO's Examination policy of initially treating and searching prior art under the broadest interpretation of a “mean for” or “steps for” claim limitation implies that the broadest initial search on 35 USC § 112(6) (post AIA 112(f)) functional limitation would have to be conducted to support a legally valid Examination on that USPTO policy for broadest interpretation of “mean for” claims. Accordingly, the USPTO may have discovered a multiplicity of prior art documents including disclosure of specific structures and elements which are suitable to act as corresponding structures to satisfy all functional limitations in the below claims that are interpreted under 35 USC § 112(6) (post AIA 112(f)) when such corresponding structures are not explicitly disclosed in the foregoing patent specification. Therefore, for any invention element(s)/structure(s) corresponding to functional claim limitation(s), in the below claims interpreted under 35 USC § 112(6) (post AIA 112(f)), which is/are not explicitly disclosed in the foregoing patent specification, yet do exist in the patent and/or non-patent documents found during the course of USPTO searching, Applicant(s) incorporate all such functionally corresponding structures and related enabling material herein by reference for the purpose of providing explicit structures that implement the functional means claimed. Applicant(s) request(s) that fact finders during any claim's construction proceedings and/or examination of patent allowability properly identify and incorporate only the portions of each of these documents discovered during the broadest interpretation search of 35 USC § 112(6) (post AIA 112(f)) limitation, which exist in at least one of the patents and/or non-patent documents found during the course of normal USPTO searching and or supplied to the USPTO during prosecution. Applicant(s) also incorporate by reference the bibliographic citation information to identify all such documents comprising functionally corresponding structures and related enabling material as listed in any PTO Form-892 or likewise any information disclosure statements (IDS) entered into the present patent application by the USPTO or Applicant(s) or any 3^{rd} parties. Applicant(s) also reserve its right to later amend the present application to explicitly include citations to such documents and/or explicitly include the functionally corresponding structures which were incorporate by reference above.

Thus, for any invention element(s)/structure(s) corresponding to functional claim limitation(s), in the below claims, that are interpreted under 35 USC § 112(6) (post AIA 112(f)), which is/are not explicitly disclosed in the foregoing patent specification, Applicant(s) have explicitly prescribed which documents and material to include the otherwise missing disclosure, and have prescribed exactly which portions of such patent and/or non-patent documents should be incorporated by such reference for the purpose of satisfying the disclosure requirements of 35 USC § 112 (6). Applicant(s) note that all the identified documents above which are incorporated by reference to satisfy 35 USC § 112 (6) necessarily have a filing and/or publication date prior to that of the instant application, and thus are valid prior documents to incorporated by reference in the instant application.

Having fully described at least one embodiment of the present invention, other equivalent or alternative methods of implementing systems and methods for simulating the spatial and temporal magnetic properties of configurable nanoscale magnetic molecules according to the present invention may be apparent to those skilled in the art. Various aspects of the invention have been described above by way of illustration, and the specific embodiments disclosed are not intended to limit the invention to the particular forms disclosed. The particular implementation of the systems and methods for simulating the spatial and temporal magnetic properties of configurable nanoscale magnetic molecules may vary depending upon the particular context or application. By way of example, and not limitation, the systems and methods for simulating the spatial and temporal magnetic properties of configurable nanoscale magnetic molecules described in the foregoing were principally directed to systems and methods for simulating the spatial and temporal magnetic properties of configurable nanoscale magnetic molecules implementations; however, similar techniques may instead be applied to other systems and methods, which implementations of the present invention are contemplated as within the scope of the present invention. The invention is thus to cover all modifications, equivalents, and alternatives falling within the spirit and scope of the following claims. It is to be further understood that not all of the disclosed embodiments in the foregoing specification may necessarily satisfy or achieve each of the objects, advantages, or improvements described in the foregoing specification.

Claim elements and steps herein may have been numbered and/or lettered solely as an aid in readability and understanding. Any such numbering and lettering in itself is not intended to and should not be taken to indicate the ordering of elements and/or steps in the claims.

The corresponding structures, materials, acts, and equivalents of all means or step plus function elements in the claims below are intended to include any structure, material, or act for performing the function in combination with other claimed elements as specifically claimed.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations may be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

The Abstract is provided to comply with 37 C.F.R. Section 1.72(b) requiring an abstract that may allow the reader to ascertain the nature and gist of the technical disclosure. That is, the Abstract is provided merely to introduce certain concepts and not to identify any key or essential features of the claimed subject matter. It is submitted with the understanding that it may not be used to limit or interpret the scope or meaning of the claims.

The following claims are hereby incorporated into the detailed description, with each claim standing on its own as a separate embodiment.

Only those claims which employ the words “means for” or “steps for” are to be interpreted under 35 USC 112, sixth paragraph (pre-AIA) or 35 USC 112(f) post-AIA. Otherwise, no limitations from the specification are to be read into any claims, unless those limitations are expressly included in the claims.

What is claimed is:

1. A method comprising;
steps for simulating molecular spintronics devices (MSD) of different shapes involving thousands of magnetic atoms and molecules by using a Heisenberg 3D atomic model analogous to intended MSD and using a configurable energy equation to represent a molecule, an electrode, and an interaction between said molecule and said electrode to simulate properties of a wide range of MSDs;
steps for representing complex magnetic molecules as a device element in MSD to use MCSMSD, wherein a MCSMSD molecule is represented by a configurable and expandable atom-like feature;
steps for defining a wide range of magnetic molecule-magnetic electrode interactions in MSD by using generic magnetism equations from prior literature;
steps for studying the magnetic anisotropy effect in MSD simulation;
steps for studying the effect of electrons in the magnetic electrodes and fluctuations;
steps for controlling the active molecule population in MSD simulation;
steps for studying the effect of defects within insulator competing with magnetic molecules; and
steps for harnessing parallel processing capabilities in desktop computers.
